(19) United States
(12) Patent Application Publication
(10) Pub. No.: US 2025/0314968 A1
(43) Pub. Date: Oct. 9, 2025

(54) SELF-ALIGNED DOUBLE PATTERNING USING METAL-BASED RESIST

(71) Applicants: Tokyo Electron Limited, Tokyo (JP); Geminatio, Inc., Schenectady, NY (US)

(72) Inventors: Phillip D. Hustad, Schenectady, NY (US); Jordan B. Greenough, Schenectady, NY (US); Max J. Klemes, Schenectady, NY (US)

(21) Appl. No.: 19/097,643

(22) Filed: Apr. 1, 2025

Related U.S. Application Data
(60) Provisional application No. 63/631,155, filed on Apr. 8, 2024.

(51) Int. Cl. G03F 7/039; G03F 7/00

(52) U.S. Cl. CPC G03F 7/039; G03F 7/70425

(57) ABSTRACT

A solubility-shifting agent (SSA) coating composition includes a solvent and an SSA configured to be diffused inward into a relief pattern from an SSA coating formed from the SSA coating composition. The SSA is configured to remain dormant within the relief pattern during a photolithographic process and diffuse outward from the relief pattern into an overcoat. The relief pattern includes a metal-based resist, a matrix polymer including at least one monomer. The solvent is configured to dissolve the SSA and the matrix polymer, but not the metal-based resist. A method for self-aligned double patterning may use the SSA coating by diffusing the SSA inward into the relief pattern, rinsing the substrate to remove the SSA coating, depositing the overcoat, diffusing the SSA outward into the overcoat to form soluble regions in the overcoat, and developing the substrate to selectively remove the soluble regions.

### CROSS-REFERENCE TO RELATED APPLICATIONS

This application claims the priority and benefit of U.S. Provisional Application No. 63/631,155, filed on Apr. 8, 2024, which application is hereby incorporated herein by reference in its entirety.

### TECHNICAL FIELD

The present disclosure relates generally to methods for forming a self-aligned double patterned mask, and more particularly, photolithography materials and processes in methods for forming a self-aligned double patterned mask during manufacturing of semiconductor devices.

### BACKGROUND

In photolithography for semiconductor manufacturing, a relief pattern can be topographical variation created on a surface of and/or through a photoresist material layer. A relief pattern can be formed when portions of a photoresist material layer are selectively exposed to light and then selectively removed, resulting in regions with different heights or levels, such as trenches and holes formed in and patterned in a layer or film of photoresist material. The photoresist material is a light-sensitive material that undergoes chemical changes when exposed to ultraviolet (UV) light, extreme ultraviolet (EUV) light (e.g., light with a wavelength of 13.5 nm) or an electron beam. The photoresist material is typically exposed to a patterned light through a mask or directly using a laser. The pattern transferred to the photoresist material by exposure to light defines exposed areas and regions of the photoresist material.

In positive photoresists, the exposed regions become soluble and can be removed in a development process by chemicals of a developer solvent. In negative photoresists, the exposed regions become insoluble, and the unexposed areas can be removed in a development process by chemicals of a developer solvent. After exposure and pattern transfer, the wafer can be subjected to a chemical developer that dissolves the soluble parts of the photoresist to create a relief pattern on the surface of and/or through the photoresist material layer, such that the exposed (or unexposed) areas are removed, leaving behind patterned features. Then, this relief pattern can be used as a mask for further processing steps, such as etching or ion implantation, to transfer the pattern (design) into underlying layers and/or a substrate of the wafer.

In material processing methodologies (such as photolithography), creating patterned layers typically involves the application of a thin layer of radiation-sensitive material, such as a photoresist coating, to an upper surface of a substrate. This radiation-sensitive material is transformed into a patterned mask that can be used to etch or transfer a pattern into an underlying layer on a substrate. Patterning of the radiation-sensitive material generally involves exposure by a radiation source through a reticle (and associated optics) onto the radiation-sensitive material using, for example, a photolithographic exposure system.

This exposure creates a latent pattern within the radiation-sensitive material which can then be developed. Developing refers to dissolving and removing a portion of the radiation-sensitive material to yield a relief pattern (topographic pattern). The portion of material removed can be either irradiated regions or non-irradiated regions of the radiation-sensitive material depending on a photoresist tone and/or type of developing solvent used. The relief pattern can then function as a mask layer defining a pattern.

Preparation and development of various films used for patterning can include thermal treatment (e.g. baking). For example, a newly applied film can receive a post-application bake (PAB) to evaporate solvents and/or to increase structural rigidity or etch resistance. Also, a post-exposure bake (PEB) can be executed to cause chemical reactions that selectively change the solubility of the photoresist film in regions exposed to the actinic radiation. Fabrication tools for coating and developing substrates typically include one or more baking modules. Some photolithography processes include coating a substrate with a thin film of bottom anti-reflective coating (BARC), followed by coating with a resist, and then exposing the substrate to a pattern of light as a process step for creating microchips. A created relief pattern can then be used as a mask or template for additional processing such as transferring the pattern into an underlying layer.

The minimum resolution attainable with a single lithographic exposure is limited, amongst other things, by the wavelength of light used (the so-called diffraction limit). Techniques such as immersion lithography can be utilized to lower the diffraction limit. Multiple patterning processes such as Self-Aligned Double Patterning (SADP) are increasingly being used for scaling semiconductor features below photolithographic limits. Multiple patterning processes can half the pitch (for each additional patterning) and thus help to achieve feature sizes that are otherwise unattainable by exposure alone.

However, multiple patterning processes are frequently costly and complex. Additionally, multiple patterning process flows can be incompatible with high volume manufacturing. Further, many multiple patterning techniques require additional process steps such as etching, deposition, development, and treatments which also increase complexity and reduce throughput. Therefore, multiple pattern processes that reduce cost, reduce complexity, and/or increase compatibility with current processes, such as metal-based resists, are desirable.

### SUMMARY

In accordance with an embodiment of the present disclosure, a solubility-shifting agent (SSA) coating composition includes a solvent and an SSA configured to be diffused inward into a relief pattern from an SSA coating formed from the SSA coating composition. The SSA is configured to remain dormant within structures of the relief pattern during a photolithographic process and also to be diffused outward from the relief pattern into an overcoat. The relief pattern includes a metal-based resist, a matrix polymer including at least one monomer. The solvent is configured to dissolve the SSA and the matrix polymer, but not the metal-based resist.

In accordance with another embodiment of the present disclosure, a method for self-aligned double patterning includes diffusing an SSA inward from an SSA coating into structures of a relief pattern formed on a substrate. The relief pattern includes a metal-based resist. The method further includes rinsing the substrate to remove the SSA coating leaving the relief pattern with metal-based resist and the SSA, depositing an overcoat including a solubility-shiftable resist in openings of the relief pattern, diffusing the SSA outward from the structures of the relief pattern into the overcoat to form soluble regions in the overcoat, and developing the substrate to selectively remove the soluble regions and form trenches between the structures of the relief pattern and remaining structures of the overcoat.

In accordance with still another embodiment of the present disclosure, a method for self-aligned double patterning includes diffusing an SSA inward from an SSA coating into structures of a relief pattern formed on a substrate. The relief pattern includes a metal-based resist. The SSA is a free ligand. The method further includes rinsing the substrate to remove the SSA coating leaving the relief pattern with the metal-based resist and the SSA, depositing an overcoat including a solubility-shiftable resist in openings of the relief pattern, diffusing the SSA outward from the structures of the relief pattern into the overcoat to form soluble regions in the overcoat, and developing the substrate to selectively remove the soluble regions and form trenches between the structures of the relief pattern and remaining structures of the overcoat. The solubility-shiftable resist includes metal atoms and organic ligands.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1I illustrate schematic cross-sectional views of an example self-aligned double patterning process where FIG. 1A shows a substrate in an initial state with a relief pattern including a metal-based resist formed thereon, FIG. 1B shows an SSA coating step, FIG. 1C shows an inward diffusion step during which the SSA is diffused into the relief pattern resulting in the relief pattern including the metal-based resist and the SSA, FIG. 1D shows a rinse step, FIG. 1E shows an overcoat step, FIGS. 1F and 1G show an outward diffusion step during which the SSA is diffused from the relief pattern into the overcoat, FIG. 1H shows a development step, and FIG. 1I shows an etching step in accordance with embodiments of the present disclosure;

FIGS. 2A-2F illustrate schematic cross-sectional views of an example self-aligned double patterning process where FIG. 2A shows an SSA coating step. FIG. 2B shows an inward diffusion step, FIG. 2C shows a rinse step, FIG. 2D shows an overcoat step during which a metal-based overcoat is deposited in openings of a relief pattern formed on a substrate and FIGS. 2E and 2F show an outward diffusion step in accordance with embodiments of the present disclosure;

FIGS. 3A-3F illustrate schematic cross-sectional views of an example self-aligned double patterning process where FIG. 3A shows an SSA coating step. FIG. 3B shows an inward diffusion step, FIG. 3C shows a rinse step, FIG. 3D shows an overcoat step during which a polymer-based overcoat is deposited in openings of a relief pattern formed on a substrate and FIGS. 3E and 3F show an outward diffusion step in accordance with embodiments of the present disclosure;

FIG. 4 illustrates a schematic view of an example SSA coating composition that includes a solvent and an SSA in accordance with embodiments of the present disclosure;

FIG. 5 illustrates a flowchart of an example method for self-aligned double patterning in accordance with embodiments of the present disclosure;

FIG. 6 illustrates a flowchart of another method for self-aligned double patterning where the overcoat includes a metal-based resist in accordance with embodiments of the present disclosure;

FIG. 7 illustrates examples of photoacid generators usable as an SSA in an SSA coating composition in accordance with embodiments of the present disclosure; and

FIG. 8 illustrates examples of thermal acid generators usable as an SSA in an SSA coating composition in accordance with embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes, including relative thicknesses and/or widths of layers and structures shown in the drawings. One of ordinary skill in the art can appreciate many possible applications and variations for other embodiments based on the following illustrative and example embodiments provided in the present disclosure.

In the present disclosure, terms such as “first”, “second”, “third”, “fourth”, and the like, can be used to describe various components, but the components are not necessarily limited by such terms, for example, regarding order, sequence, importance, or number of such components possible in an embodiment. Such terms can be used merely for the purpose of distinguishing one component from other components in a given embodiment or group of embodiments. Because semiconductor geometries and sizes can be so extremely small (e.g., on the order of 1 to 5 nm), the terms “film” and “layer” may be used interchangeably herein.

Ever continuous scaling can require improved patterning resolution. One approach is spacer technology to define a sub-resolution line feature via atomic layer deposition (ALD). One challenge, however, is that if the opposite tone feature is desired, using spacer techniques can involve a complex succession of operations, including over-coating with another material (an “overcoat”), using the spacer features as mandrels, chemical mechanical planarization (CMP), and reactive ion etch (RIE) to exhume the spacer material leaving a narrow trench, which can be costly. In such cases, spacer techniques can involve a complex and costly succession of steps, including over-coating with another material (an “overcoat”) using the spacer features as mandrels, chemical-mechanical planarization (CMP) to reveal the spacer features, and reactive ion etching (RIE) to remove the spacer material, leaving a narrow trench.

Self-aligned approaches, such as anti-spacer techniques, can use the diffusion length of a reactive species across a boundary between an overcoat and an adjacent layer to define a critical dimension (CD), creating a narrow trench around the features of that adjacent layer after development of the overcoat or creating a narrow trench into the features of that adjacent layer after development of the diffusion-changed regions. The CD itself can be tuned based on the physical and chemical properties of the reactive species (e.g., its molecular weight and affinity for interactions with the host material) and by modifying the bake temperature and bake time in a PEB (post exposure bake). As a result, patterning of narrow features at dimensions beyond the reach of advanced lithographic capabilities are possible.

In a so-called “freeze-less” method for self-aligned double patterning, a relief pattern is formed on a substrate from a layer of photoresist by exposing the photoresist layer to actinic radiation that includes a certain wavelength to activate a photoacid generator (PAG). The photoresist layer includes the PAG. A coating including a solubility-shifting agent (SSA) is deposited over the relief pattern. The SSA is diffused into the relief pattern and the coating is removed. A deprotectable resin is then deposited in the openings of the relief pattern. The SSA is activated and diffused a predetermined distance into the deprotectable resin forming soluble regions in the deprotectable resin. In particular, the activated SSA deprotects the resin in the diffusion region rendering the previously insoluble regions soluble in a developer. The relief pattern also remains insoluble in the developer so that when the substrate is developed, only the soluble regions are removed.

In advanced photolithography, such as extreme ultraviolet (EUV) photolithography processes, metal-based photoresists are becoming increasingly important. Conventional freeze-less self-aligned double patterning processes are not compatible with metal-based resists, such as metal-based EUV resists. In particular, formulations for coating that includes an SSA that can be diffused into a relief pattern including a metal-based resist while meeting the unique requirements of freeze-less self-aligned double patterning processes have so far not been disclosed. Consequently, improved SSA coating compositions that are compatible both with advanced photolithographic processes and with freeze-less self-aligned double patterning processes are desirable.

In accordance with embodiments herein described, the invention proposes both compositions of SSA coatings and processes to use them in methods for self-aligned double patterning. In various embodiments, an SSA coating includes a solvent and an SSA (although the solvent may be omitted in some implementations). The SSA is configured to diffuse inward from the SSA coating into structures of a relief pattern formed on a substrate during an inward diffusion process. The relief pattern includes a metal-based resist that was patterned during a photolithographic process (e.g., including metal atoms and organic radiation-sensitive ligands) to form the structures of the relief pattern. The SSA is further configured to diffuse outward from the structures of the relief pattern and into an overcoat during an outward diffusion process. For example, the diffused SSA may change (i.e., shift) the solubility of a region of the overcoat enabling the formation of pairs of trenches on opposing sides of each structure (e.g., a line) of the relief pattern (hence, “double” patterning).

In various embodiments, a method for self-aligned double patterning includes diffusing a solubility-shifting agent (SSA) inward from an SSA coating into structures of a relief pattern formed on a substrate. The relief pattern includes a metal-based resist. The SSA coating is formed from an SSA coating composition including the SSA and which may include a solvent, a matrix polymer, and additional components, such as an attachment agent. The substrate is rinsed to remove the SSA coating leaving the relief pattern with metal-based resist and the SSA. The method further includes depositing an overcoat comprising a solubility-shiftable resist in openings of a relief pattern formed on a substrate, diffusing the SSA from structures of the relief pattern a predetermined distance into the overcoat to form soluble regions in the overcoat, and developing the substrate to selectively remove the soluble regions and form trenches between the structures of the relief pattern and remaining structures of the overcoat. The predetermined distance may be from about 3 nm to 50 nm in some embodiments and between about 5 nm and 15 nm in one embodiment. The trenches formed between the structures of the relief pattern and the overcoat may function as a mask (e.g., a self-aligned, double patterned etch mask). The substrate may then be etched through the mask.

In one embodiment, the SSA is activated before, after or during the outward diffusion, such as by applying heat or radiation. The activation may generate a free SSA in the relief pattern (e.g., before or during diffusion), or may initiate solubility-shifting interactions between the SSA and a solubility-shiftable composition in the overcoat.

The relief pattern may be formed using a photolithographic process (e.g., an EUV photolithographic process). For example, a layer of photoresist coating that includes the metal-based resist (e.g., formed by depositing a photoresist precursor solution on the substrate, such as by spin coating) may be exposed to actinic radiation (e.g., EUV radiation) and then developed to form the relief pattern on the substrate.

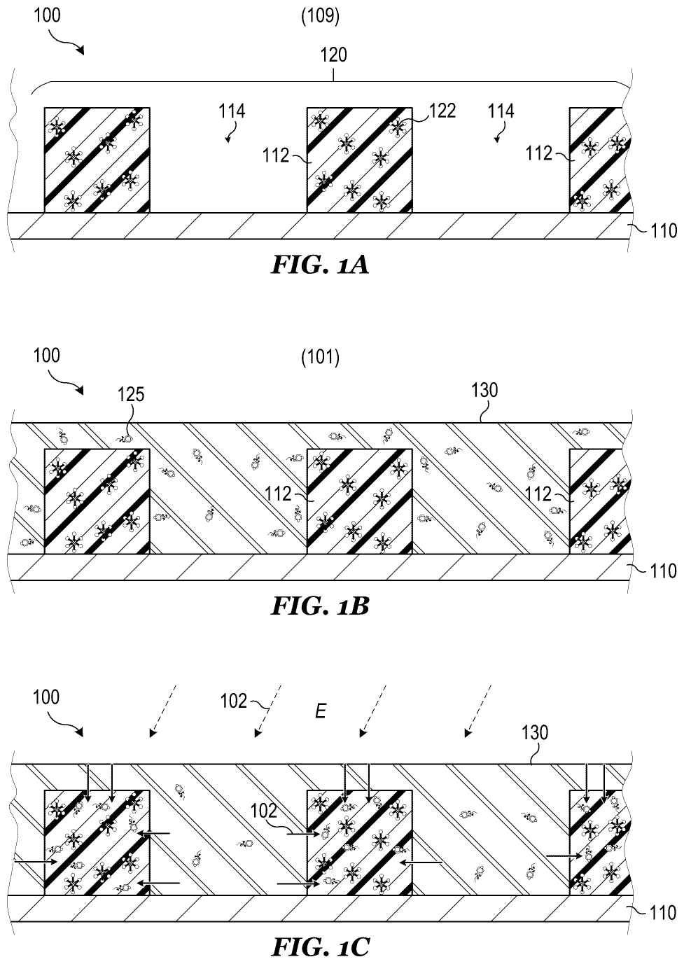

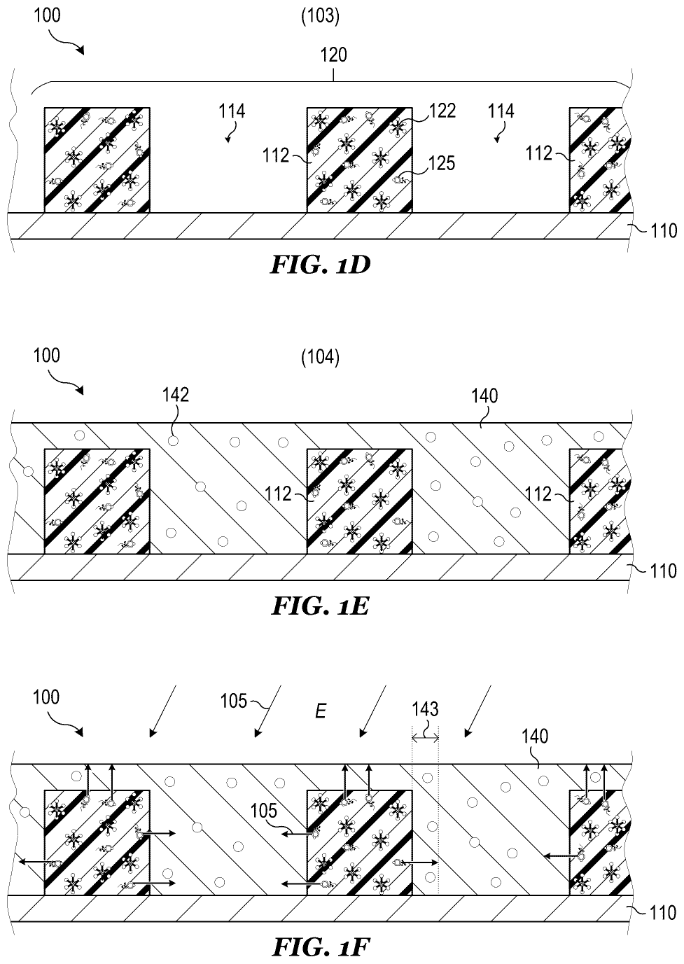

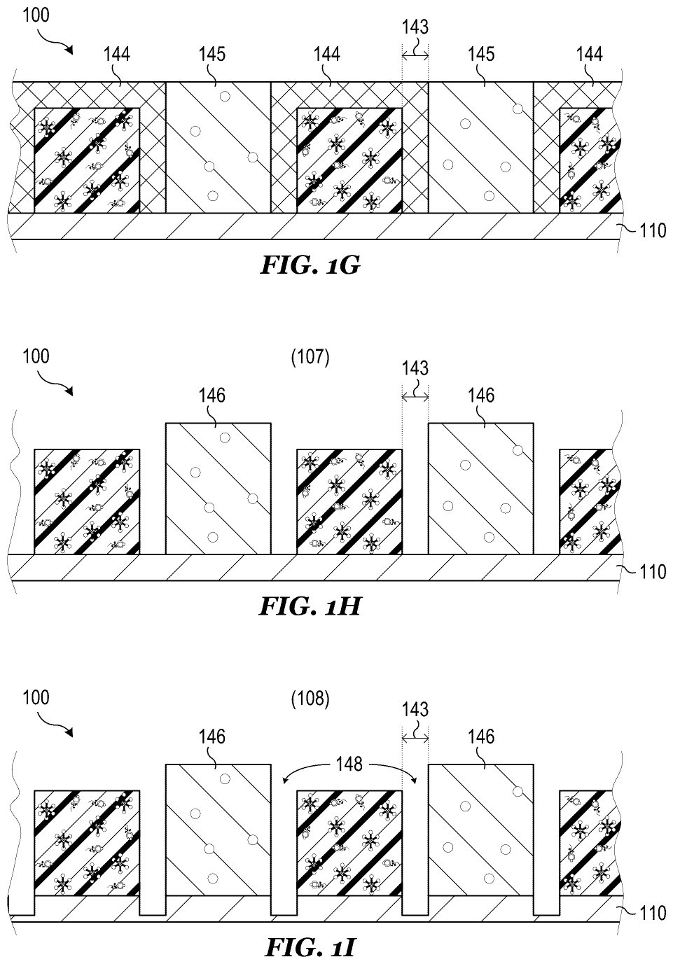

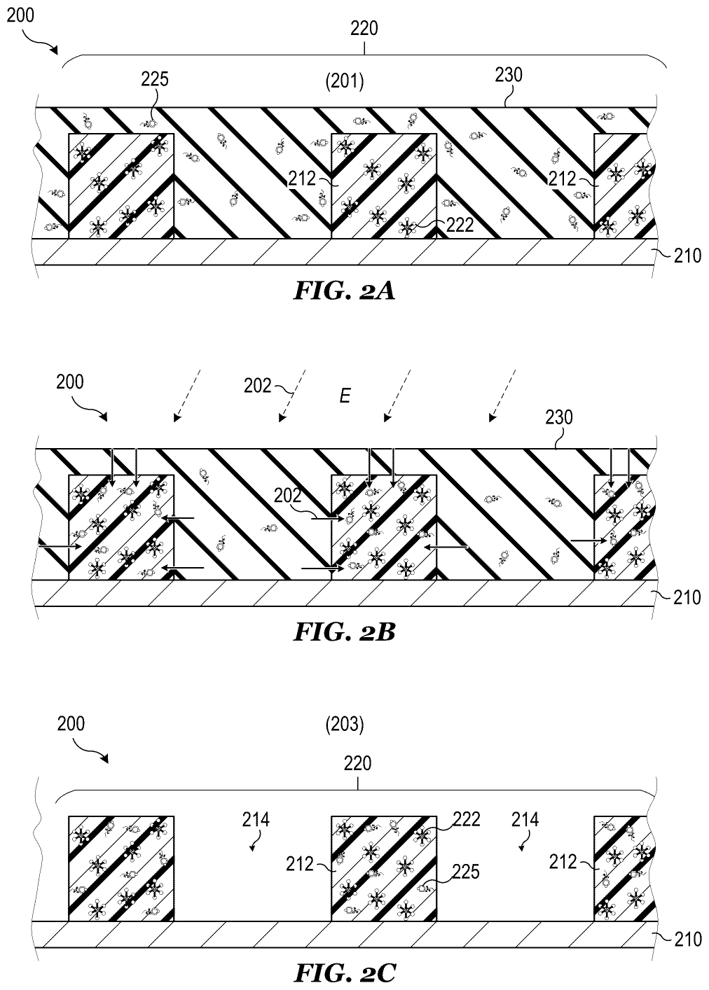

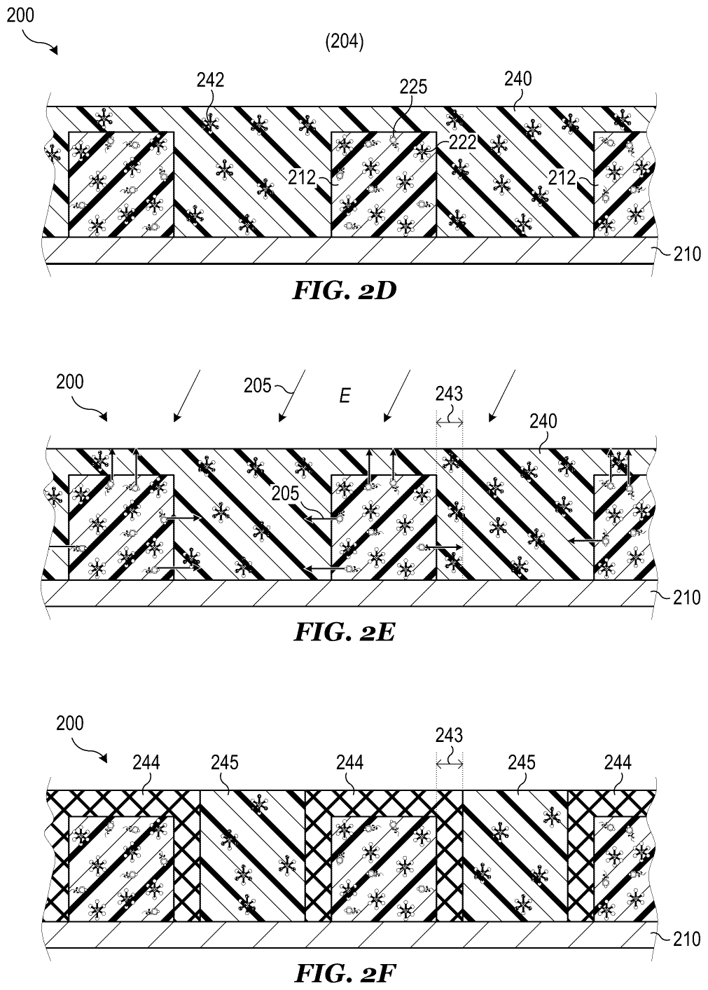

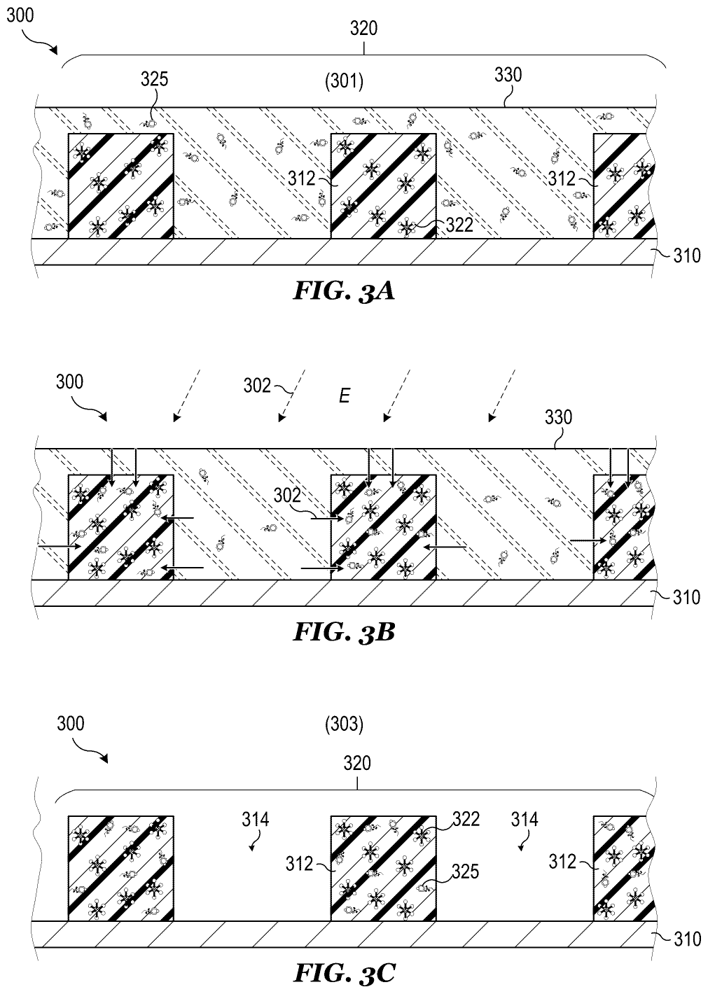

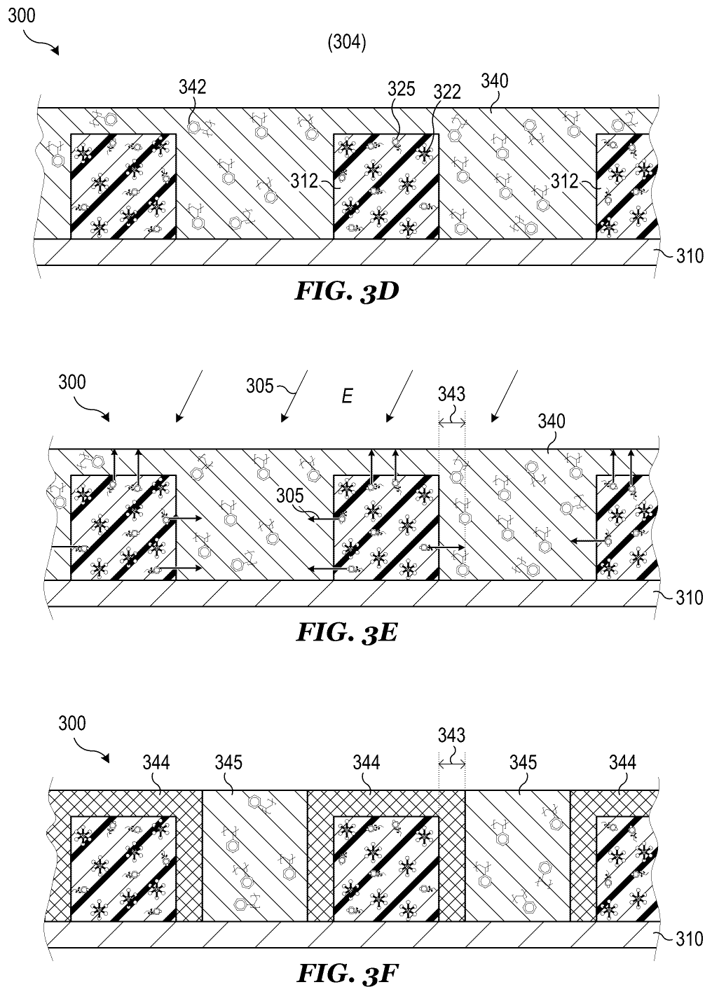

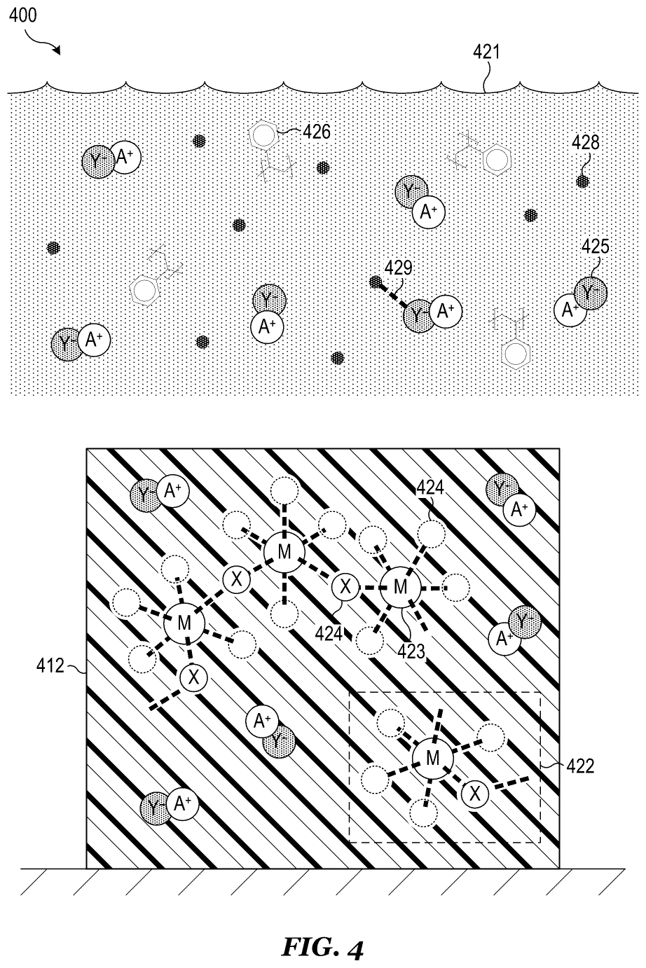

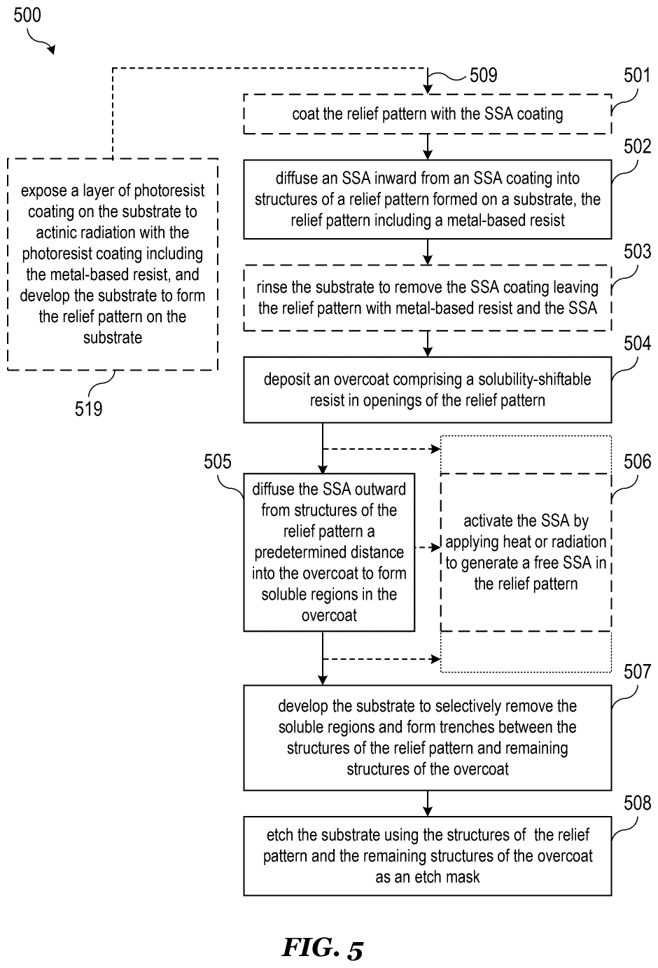

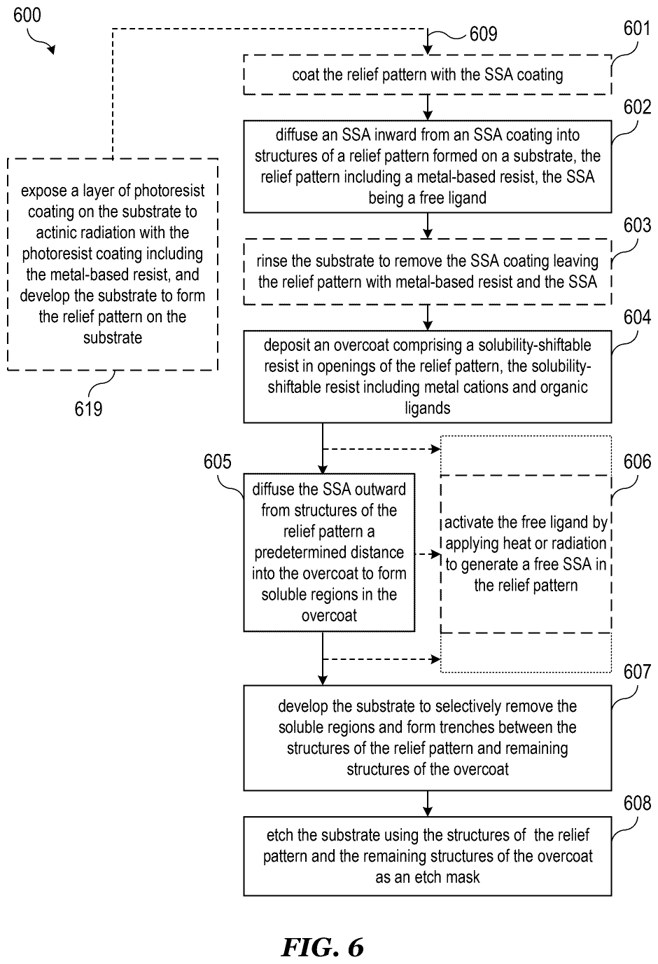

Embodiments provided below describe various methods for forming a self-aligned double patterned mask, and in particular embodiments, methods for forming a self-aligned double patterned mask that use an SSA coating including an SSA that is deposited over a relief pattern formed using a photoresist precursor solution that includes a metal-based resist. The following description describes the embodiments. FIGS. 1A-1I are used to describe an example self-aligned double patterning process. Two more example self-aligned double patterning processes are described using FIGS. 2A-2E and 3A-3E. An example SSA coating composition that can be applied as an SSA coating used to diffuse an SSA inward into a relief pattern on the substrate is described using FIG. 4. FIGS. 5 and 6 are used to describe two methods for self-aligned double patterning.

FIGS. 1A-1I illustrate schematic cross-sectional views of an example self-aligned double patterning process where FIG. 1A shows a substrate in an initial state with a relief pattern including a metal-based resist formed thereon, FIG. 1B shows an SSA coating step, FIG. 1C shows an inward diffusion step during which the SSA is diffused into the relief pattern resulting in the relief pattern including the metal-based resist and the SSA, FIG. 1D shows a rinse step, FIG. 1E shows an overcoat step, FIGS. IF and 1G show an outward diffusion step during which the SSA is diffused from the relief pattern into the overcoat, FIG. 1H shows a development step, and FIG. 1I shows an etching step in accordance with embodiments of the present disclosure.

Referring to FIGS. 1A and 1B, a self-aligned double patterning process 100 begins with a substrate 110 in an initial state 109 where a relief pattern 120 has been formed on the substrate 110. The relief pattern 120 has structures 112 separated by openings 114 that expose underlying surfaces of the substrate 110. The relief pattern 120 is formed of a material that includes a metal-based resist 122. For example, the relief pattern 120 may be formed from a photoresist precursor solution that includes the metal-based resist 122, such as dissolved in an organic solvent with or without additional additives (like a binder, for example).

The metal-based resist 122 is configured to be photoactive and may be deposited as part of a photoresist precursor solution onto the substrate 110 to form a photoresist coating. The photoactive nature of the metal-based resist 122 may be used to form the relief pattern 120 from the photoresist coating. For example, a layer of photoresist coating including the metal-based resist 122 may be exposed to actinic (e.g., EUV) radiation during an exposure step of a photolithographic process. The substrate 110 with the exposed photoresist coating may then be developed to form the structures 112 on the substrate 110. Of course, the photolithographic process may include various other steps, including baking steps such as a PAB and/or a PEB, planarization steps, cleaning steps, additional exposure steps, additional layer formation steps, and the like.

The metal-based resist 122 may be an organometallic resist. In some embodiments, the organometallic resist may include compounds or units with the formula RₓM(OR′)_{y} where M is a metal (atom or cluster) and R/R′ are similar or different organic groups. In various embodiments, the organometallic resist includes a metal polynuclear oxo/hydroxo cation with organic ligands. For example, the organic ligands may have metal carbon bonds (M—C) and/or metal carboxylate bonds (M-(O(O)CR)). The metal polynuclear oxo/hydroxo cation with the organic ligands may, for example, form an oxo-hydroxo network that has both M—O—H linkages and M—O—M linkages. Additional details of suitable compounds for the metal-based resist 122 are provided in the definitions section.

In an SSA coating step 501 of the process 100, an SSA coating 130 including an SSA 125 is formed over the relief pattern 120 so that at least vertical surfaces (i.e., substantially vertical surfaces, sidewalls) of the structures 112 are covered with the SSA coating 130. In some embodiments, the SSA coating 130 may fill the openings 114 of the relief pattern 120 (as shown). In other embodiments, a thin layer of the SSA coating 130 may cover the sidewalls and top surfaces of the structures 112. In various embodiments, the SSA coating 130 selectively attaches to the structures 112 and forms a few layers of the SSA coating 130. In one embodiment, the SSA coating 130 is substantially a monolayer.

The SSA coating 130 may be formed from an SSA coating composition that includes at least the SSA 125 and may include other components, such as a matrix polymer, an attachment agent, and others as well as a solvent to dissolve the other components. When included, the attachment agent is configured to promote adhesion of the SSA 125 and/or other components of the SSA coating 130 to the relief pattern 120.

As shown in FIG. 1C, during an inward diffusion step 102, the SSA 125 is diffused inward into the structures 112 of the relief pattern 120. Energy (shown schematically as E) may be supplied to initiate and or control the diffusion process. For example, thermal energy may be applied to all or some of the substrate 110 during the inward diffusion step 102. In some embodiments, the inward diffusion step 102 is a baking process, and is an SSA coating PAB in one embodiment. Alternatively, the SSA 125 may not diffuse inward, but instead remain on the surface of the structures 112 of the relief pattern 120 in some embodiments, such as chemisorbed or physisorbed substantially on or near the surface (and not substantially in the bulk of the structures 112).

Turning now to FIG. 1D, the substrate 110 may be rinsed in an optional rinse step 103 to remove the SSA coating 130 leaving the relief pattern 120 with the metal-based resist 122 and SSA 125. The rinse step 103 is optional because in some embodiments, the SSA 125 is provided by itself or forms a thin layer than does not need to be removed. The rinse step 503 may be omitted in some embodiments, such as when the SSA coating 130 only includes SSA 125 or when the SSA coating is a monolayer or few layers that are bonded to the structures of the relief pattern, as examples.

Referring to FIG. 1E, an overcoat 140 is formed over the relief pattern 120 during an overcoat step 104 so that the overcoat 140 is deposited in the openings 114 between the structures 112. The overcoat 140 is formed of a material that includes a solubility-shiftable resist 142. For example, the overcoat 140 may be formed from an overcoat composition that includes the solubility-shiftable resist 142, such as dissolved in a solvent, and may also include additional additives.

The SSA 125 is configured to produce a localized change in the solubility of the solubility-shiftable resist 142 included in the overcoat 140. The SSA 125 may take a variety of forms, the specific details of which may depend on the context of a given application as may be apparent to those of skill in the art in view of the present disclosure. In various embodiments, the SSA 125 is an acid-based SSA such as a free acid, a PAG (photoacid generator), or a thermal acid generator (TAG. In other embodiments, the SSA is based on a basic group or compound such as a photobase generator (PBG) or a thermal base generator (TBG). In still other embodiments, the SSA may be a photodestroyable quencher (PDQ), a crosslinker, an oxidizing agent, a reducing, agent, and others. Additional details of suitable compounds for the SSA 125 are provided in the definitions section.

Referring to FIG. 1F, the SSA 125 is diffused from the structures 112 of the relief pattern 120 into the overcoat 140 a predetermined distance 143 during an outward diffusion step 105. Energy (shown schematically as E) may be supplied to initiate and or control the diffusion process. For example, thermal energy may be applied to all or some of the substrate 110 during the outward diffusion step 105.

In one embodiment, the outward diffusion step 105 is a baking process, such as a PAB of the overcoat 140. The predetermined distance 143 may be tightly controlled, such as through selection of the SSA 125, the solubility-shiftable resist 142, and other materials of the relief pattern 120 and/or the overcoat 140 as well as by controlling the application of energy both in magnitude and duration.

Now referring to FIG. 1G, the outward diffusion step 105 results in soluble regions 144 and insoluble regions 145. That is, the SSA 125 effects a change in the solubility of the overcoat 140 in the regions into which it is diffused (the predetermined distance 143 into the overcoat 140) and does not affect the solubility of the insoluble regions 145. The soluble regions 144 are soluble in a predetermined developer while both the insoluble regions 145 and the structures 112 of the relief pattern 120 remain insoluble in the predetermined developer.

In some embodiments, the SSA 125 changes the solubility of the overcoat 140 merely by virtue of being diffused. In other embodiments, additional energy (e.g., thermal, actinic, etc.) may be applied to the overcoat 140 to activate or enhance the shift in solubility. In one embodiment, the additional energy is provided by the thermal energy applied to diffuse the SSA 125 during the outward diffusion step 105.

Turning to FIG. 1H, the substrate 110 is developed during a development step 107 to remove the soluble regions 144 leaving the structures 112 and remaining structures 146 (previously the insoluble regions 145) on the substrate 110, as shown. The process of the development step 107 produces a pair of trenches 148 from one line (on either side of each of the structures 112), hence the term double patterning. The dimensions of the trenches 148 is determined by the predetermined distance 143.

A possible advantage of the controllability of the outward diffusion step 105 is to define the critical dimension (CD) of the predetermined distance 143 to be both small and uniform. For example, the CD of the trenches 148 (and the predetermined distance 143) may on the order of tens of nanometers, and is on the order of single digits of nanometers in some embodiments. In various embodiments, the CD of the trenches 148 (and the predetermined distance 143) is less than about 10 nm and is between about 10 nm and about 3 nm in some embodiments. In one embodiment, the CD of the trenches 148 (and the predetermined distance 143) is about 3 nm.

Turning to FIG. 1I, the substrate 110 may be etched using the structures 112 of the relief pattern 120 and the remaining structures 146 of the overcoat 140 as an etch mask during an etching step 108 to extend the trenches 148 into the underlying surface of the substrate 110. Again, the CD of the trenches 148 that extend into the substrate 110 may be advantageously small and uniform by controlling the diffusion of the SSA 125 and resulting solubility shift in the overcoat 140 during the outward diffusion step 105.

FIGS. 2A-2F illustrate schematic cross-sectional views of an example self-aligned double patterning process where FIG. 2A shows an SSA coating step. FIG. 2B shows an inward diffusion step, FIG. 2C shows a rinse step, FIG. 2D shows an overcoat step during which a metal-based overcoat is deposited in openings of a relief pattern formed on a substrate and FIGS. 2E and 2F show an outward diffusion step in accordance with embodiments of the present disclosure. The self-aligned double patterning process of FIGS. 2A-2E may be a specific implementation of other processes described herein such as the self-aligned double patterning process of FIGS. 1A-1I, for example. Similarly labeled elements may be as previously described.

Referring to FIG. 2A, a self-aligned double patterning process 200 is shown after SSA coating step 201 during which an SSA coating 230 is formed over structures 212 of a relief pattern 220 of a substrate 210. It should be noted that here and in the following a convention has been adopted for brevity and clarity wherein elements adhering to the pattern [x20] where ‘x’ is the figure number may be related implementations of a relief pattern in various embodiments. For example, the relief pattern 220 may be similar to the relief pattern 120 except as otherwise stated. An analogous convention has also been adopted for other elements as made clear by the use of similar terms in conjunction with the aforementioned numbering system. For example, the SSA coating 230 may be similar to the SSA coating 130 and so on.

Now referring to FIG. 2B, the SSA 225 is diffused inward from the SSA coating 230 into the structures 212 of the relief pattern 220 during an inward diffusion step 202. The relief pattern 220 includes a metal-based resist 222, as before so that after an optional rinse step 203, the structures 212 that remain on the substrate 210 include the metal-based resist 222 and the SSA 225, as shown in FIG. 2C.

Referring now to FIG. 2D, an overcoat 240 is formed in openings 214 between the structures 212 of the relief pattern 220 during an overcoat step 204. In this specific example, the overcoat 240 is formed of a material that also includes a metal-based resist (as a solubility-shiftable resist 242). The metal-based resist of the overcoat 240 may be independently selected from a similar class of materials as the metal-based resist 222 (i.e., the metal-based resist used as the solubility-shiftable resist 242 may be identical, substantially similar, or different from the metal-based resist 222 of the relief pattern 220).

In one embodiment, the metal-based resist used as the solubility-shiftable resist 242 in the overcoat 240 is substantially similar to the metal-based resist 222 in the relief pattern 220 (including some different ligands, but being at least similar in some aspects, such as type of metal). In other embodiments, the metal-based resist of the overcoat 240 is substantially different from the metal-based resist 222, such as having substantially different ligands or a different metal.

The SSA 225 is again configured to produce a localized change in the solubility of the solubility-shiftable resist 242 included in the overcoat 240. The SSA 225 may take any of the variety of forms previously described. Additionally, however, some forms of the SSA 225 may be enabled through the use of the metal-based resist as the solubility-shiftable resist 242. For example, oxidation chemistry of the metal may be leveraged in some cases by selecting the SSA 225 to be an oxidizing agent or a reducing agent. When included as the SSA 225, the oxidizing agent or the reducing agent may alter the oxidation state of the metal in the metal-based resist causing the desired local solubility shift in the overcoat 240. Or course, other forms of the SSA 225 are also possible, depending on the specific details of a given application.

Referring now to FIGS. 2E and 2F, the SSA 225 is diffused from the structures 212 of the relief pattern 220 into the overcoat 240 a predetermined distance 243 during an outward diffusion step 205. The outward diffusion step 205 results in soluble regions 244 and insoluble regions 245. The substrate 210 may then be developed and etched during a subsequent development and etch steps, as previously described.

FIGS. 3A-3F illustrate schematic cross-sectional views of an example self-aligned double patterning process where FIG. 3A shows an SSA coating step. FIG. 3B shows an inward diffusion step, FIG. 3C shows a rinse step, FIG. 3D shows an overcoat step during which a polymer-based overcoat is deposited in openings of a relief pattern formed on a substrate and FIGS. 3E and 3F show an outward diffusion step in accordance with embodiments of the present disclosure. The self-aligned double patterning process of FIGS. 3A-3E may be a specific implementation of other processes described herein such as the self-aligned double patterning process of FIGS. 1A-1I, for example. Similarly labeled elements may be as previously described.

Referring to FIGS. 3A and 3B, a self-aligned double patterning process 300 is shown after SSA coating step 301 during which an SSA coating 330 is formed over structures 312 of a relief pattern 320 of a substrate 310. The SSA 325 is diffused inward from the SSA coating 330 into the structures 312 of the relief pattern 320 during an inward diffusion step 302. The relief pattern 320 includes a metal-based resist 322, as before so that after an optional rinse step 303, the structures 312 that remain on the substrate 310 include the metal-based resist 322 and the SSA 325, as shown in FIG. 3C.

Now referring to FIG. 3D, an overcoat 340 is formed in openings 314 between the structures 312 of the relief pattern 320 during an overcoat step 304. In this specific example, the overcoat 340 is formed of a material that also includes a polymer-based resist (as a solubility-shiftable resist 342). The polymer-based resist of the solubility-shiftable resist 342 may be a homopolymer or a copolymer having a plurality of distinct repeat units (also referred to as monomers). The polymer-based resist may include a polymer composed of monomers including vinyl monomers such as styrene, acrylate, methacrylate, norbornene, or combinations thereof, as well as other monomers that can be polymerized into a polymer. The polymer may include one or more monomers with reactive functional groups. Additional details of suitable compounds for the polymer-based resist of the solubility-shiftable resist 342 are provided in the definitions section.

The SSA 325 is again configured to produce a localized change in the solubility of the solubility-shiftable resist 342 included in the overcoat 340. The SSA 325 may take any of the variety of forms previously described. For example, the SSA 325 may be an acid-based SSA such as a free acid, a PAG, or a TAG, an SSA with a basic group or compound such as a PBG or TBG, PDQ, a crosslinker, an oxidizing agent, a reducing agent, and others. In some cases, the polymer-based resist used as the solubility-shiftable resist 342 may influence the selection of the SSA 325 differently than the metal-based resist of the solubility-shiftable resist 242. For example, certain SSA types, such as oxidizing agents and reducing agents, may not be desirable or possible for use as the SSA 325 with the polymer-based resist of the solubility-shiftable resist 342.

Referring now to FIGS. 3E and 3F, the SSA 325 is diffused from the structures 312 of the relief pattern 320 into the overcoat 340 a predetermined distance 343 during an outward diffusion step 305. The outward diffusion step 305 results in soluble regions 344 and insoluble regions 345. The substrate 310 may then be developed and etched during a subsequent development and etch steps, as previously described.

FIG. 4 illustrates a schematic view of an example SSA coating composition that includes a solvent and an SSA in accordance with embodiments of the present disclosure. The SSA coating composition of FIG. 4 may be used to form SSA coatings used in any of the processes described herein, such as the self-aligned double patterning process of FIGS. 1A-1I, for example. Similarly labeled elements may be as previously described.

Referring to FIG. 4, an SSA coating composition 400 includes at least an SSA 425, but may include various other components, such as an optional matrix polymer 426 or an optional attachment agent 428, and may be dissolved in a solvent 421, for example. In various embodiments, the SSA coating composition 400 is configured to be formed over structures 412 of a relief pattern (e.g., deposited, such as using a spin coating process, for example). When included, the optional attachment agent 428 may be bonded together with the SSA 425 in the same complex or molecule (conceptually indicated by the optional bond 429). The SSA 425 is configured to be diffused into or attached to the structures 412 of the relief pattern so that the structures include both a metal-based resist 422 and the SSA 425. The metal-based resist 422 includes metal atoms 423 and organic ligands 424.

In various embodiments, the matrix polymer 426 is formed from one or more monomers and may include a monomer having an ethylenically unsaturated polymerizable double bond. Some categories of monomers that may be included in the optional matrix polymer 426 include (meth)acrylate monomers, vinyl-based monomers (e.g., vinyl aromatic monomers, and others), maleic-based monomers, norbornene-based monomers, and combinations thereof. The matrix polymer may also include any combination of the above-mentioned monomers.

In various embodiments, the attachment agent 428 is a selective attachment agent that is configured to preferentially adhere to the relief pattern relative to other materials, such as exposed surfaces of substrate in openings of the relief pattern. For example, the selective attachment agent may include a chemical functional group that can be further functionalized. Some possible selective attachment agents include, but are not limited to, alcohols, silanols, amines, phosphines, phosphonic acids, and carboxylic acids. In one embodiment, the attachment agent facilitates formation of a monolayer coating on the relief pattern. Additional details of suitable compounds for the matrix polymer and/or the attachment agent are provided in the definitions section.

FIG. 5 illustrates a flowchart of an example method for self-aligned double patterning in accordance with embodiments of the present disclosure. The method of FIG. 5 may be combined with other methods and processes as well as be performed using the systems and apparatuses described herein. For example, the method of FIG. 5 may be combined with any of the embodiments of FIGS. 1A-4. The method steps of FIG. 5 may be performed in any suitable order or concurrently with one another as may be apparent to a person of skill in the art.

Referring to FIG. 5, a method 500 for self-aligned double patterning includes an inward diffusion step 502 during which an SSA is diffused inward from an SSA coating into structures of a relief pattern formed on a substrate. The relief pattern includes a metal-based resist. The SSA may be absorbed into the relief pattern without the application of additional energy (e.g., at room temperature, processing temperature, storage temperature, etc.). In some embodiments, additional energy (e.g., thermal energy in the form of a bake, for example) may be supplied to cause or enhance diffusion of the SSA inward into the structures of relief pattern. Alternatively or additionally, the SSA may attach to surfaces or remain substantially on the surface of the structure of the relief pattern (rather than diffusing substantially into the structures).

The substrate may then be rinsed to remove the SSA coating during a rinse step 503 leaving the relief pattern with the metal-based resist and the SSA. Optionally, the rinse step 503 may be omitted (such as when the SSA coating only includes an SSA, when the SSA coating is a monolayer or few layers that are bonded to the structures of the relief pattern, etc.).

The method 500 further includes an overcoat step 504 during which an overcoat including a solubility-shiftable resist is deposited in openings of the relief pattern. In an outward diffusion step 505, the SSA is diffused outward from structures of the relief pattern a predetermined distance into the overcoat to form soluble regions in the overcoat.

In some embodiments, the SSA may be activated by applying energy (e.g., heat or radiation) to generate a free SSA in the relief pattern. Alternatively or additionally, the optional activation of the SSA may take place in the overcoat to induce or enhance a solubility-shifting interaction (e.g., reaction), between the SSA and the solubility-shiftable resist. Further, as shown, the optional activation step 506 may be performed before, during, and/or after the outward diffusion step 505.

After the formation of the soluble regions during the outward diffusion step 505 (and/or the optional activation step 506), the substrate is developed to selectively remove the soluble regions and form trenches between the structures of the relief pattern and remaining structures of the overcoat during a development step 507. In an etching step 508 (which may or may not be considered part of the self-aligned double patterning process itself), the substrate may then be etched using the structures of the relief patter and the remaining structures of the overcoat as an etch mask.

Optionally, an SSA coating step 501 may be included during which the relief pattern is coated with the SSA coating, such as using a spin coating method, for example. Before the SSA coating step 501, the substrate is in an initial state 509 with the relief pattern formed thereon. The SSA and the SSA coating are configured to be compatible with the metal-based resist of the relief pattern. That is, the components of an SSA coating composition that may be used to form the SSA coating (e.g., a solvent) are configured to not disrupt the structures of the relief pattern (e.g., not dissolve the metal-based resist, for example). By comparison, when a solvent is included in the SSA coating composition, the solvent dissolve the SSA (as well as other components such as an attachment agent), but not dissolve the relief pattern.

Also optional from the perspective that the relief pattern on the substrate may already be formed (the initial state 509) prior to the initiation of the method 500, a photolithographic process 519 may also be included as part of the method 500. The photolithographic process 519 may include an exposure step during which a layer of photoresist coating on the substrate is exposed to actinic radiation (e.g., EUV radiation). The photoresist coating includes the SSA and the metal-based resist. After the exposure step, the substrate may be developed during a development step to form the relief pattern on the substrate.

FIG. 6 illustrates a flowchart of another method for self-aligned double patterning where the overcoat includes a metal-based resist in accordance with embodiments of the present disclosure. The method of FIG. 6 is a specific example of the method of FIG. 5 where the soluble regions of the overcoat are formed using a reaction between an SSA including a free ligand and a metal-based resist in the overcoat. The method of FIG. 6 may be combined with other methods and processes as well as be performed using the systems and apparatuses described herein. For example, the method of FIG. 6 may be combined with any of the embodiments of FIGS. 1A-4. The method steps of FIG. 6 may be performed in any suitable order or concurrently with one another as may be apparent to a person of skill in the art.

Referring to FIG. 6, a method 600 for self-aligned double patterning includes an inward diffusion step 602 during which an SSA is diffused inward from an SSA coating into structures of a relief pattern formed on a substrate. The relief pattern includes a metal-based resist and the SSA is includes free ligands. The substrate may then be rinsed to remove the SSA coating during a rinse step 603 leaving the relief pattern with the metal-based resist and the SSA. Optionally, the rinse step 603 may be omitted (such as when the SSA coating only includes an SSA, when the SSA coating is a monolayer or few layers that are bonded to the structures of the relief pattern, etc.).

The method 600 further includes an overcoat step 604 during which an overcoat including a solubility-shiftable resist is deposited in openings of the relief pattern. The solubility-shiftable resist includes metal atoms and organic ligands (i.e., it is a metal-based resist). In an outward diffusion step 605, the SSA is diffused outward from structures of the relief pattern a predetermined distance into the overcoat to form soluble regions in the overcoat.

In some embodiments, the free ligand of the SSA may be activated by applying energy (e.g., heat or radiation) to generate a free SSA in the relief pattern. Alternatively or additionally, the optional activation of the SSA may take place in the overcoat to induce or enhance a solubility-shifting interaction (e.g., reaction), between the SSA and the solubility-shiftable resist. Further, as shown, the optional activation step 606 may be performed before, during, and/or after the outward diffusion step 605.

After the formation of the soluble regions during the outward diffusion step 605 (and/or the optional activation step 606), the substrate is developed to selectively remove the soluble regions and form trenches between the structures of the relief pattern and remaining structures of the overcoat during a development step 607. In an etching step 608 (which may or may not be considered part of the self-aligned double patterning process itself), the substrate may then be etched using the structures of the relief patter and the remaining structures of the overcoat as an etch mask.

Optionally, an SSA coating step 601 may be included during which the relief pattern is coated with the SSA coating, such as using a spin coating method, for example. Before the SSA coating step 601, the substrate is in an initial state 609 with the relief pattern formed thereon. The SSA and the SSA coating are configured to be compatible with the metal-based resist of the relief pattern. Also optional from the perspective that the relief pattern on the substrate may already be formed (the initial state 609) prior to the initiation of the method 600, a photolithographic process 619 may also be included as part of the method 600.

For describing some example materials that can be implemented and used in an embodiment of the present disclosure, some example definitions will be provided next. These definitions are intended to supplement and illustrate, not preclude, definitions known to those of skill in the art, as can be apparent to one of ordinary skill in the art to which the present disclosure pertains.

### Photoresist Precursor Solution

In embodiments of the present disclosure, a photoresist precursor solution may be used to form the relief pattern on the substrate. The photoresist precursor solution includes a photoactive metal-based resist, and may also include additional, optional components, such as an organic solvent, a photoacid generator, a binder, a quencher, and others. The photoresist precursor solution may be deposited on the substrate as a photoresist coating, by any method known in the art, such as spin coating or dry deposition, for example. One or more of the components of the photoresist precursor solution (such as the organic solvent) may be removed from the photoresist coating during various processes, such as spin coating, baking (e.g. PAB and PEB), and others.

The relief pattern is formed by exposing desired regions of the photoresist coating to actinic radiation and developing the substrate to remove photoresist coating material. Either the exposed or unexposed portions of the photoresist coating may be removed by the developer, depending on the tone of the resist, which may be selected based on the specific details of a given application. In various embodiments, the metal-based resist is sensitive to the EUV portion of the electromagnetic spectrum, and is an EUV photoresist in one embodiment.

### Metal-based Resist in the Photoresist Precursor Solution

The metal-based resist may be an organometallic resist. In some embodiments, the organometallic resist may include compounds or units with the formula RₓM(OR′)_{y} where M is a metal (atom or cluster) and R/R′ are similar or different organic groups. In various embodiments, the organometallic resist includes a metal polynuclear oxo/hydroxo cation with organic ligands. For example, the organic ligands may attach to the metal cation via metal carbon bonds (M—C), metal oxygen bonds (e.g. metal carboxylate: M-(O(O)CR), metal alkoxide: M—O—R) and/or metal heteroatom bonds (e.g. M—N—R, M—S—R, M—P—R, etc.). The metal polynuclear oxo/hydroxo cation with the organic ligands may, for example, form an oxo-hydroxo network that has both M—O—H linkages and M—O—M linkages.

In some embodiments, the photoresist precursor solution for forming the photoresist coating includes at least one complex, which may be described by the chemical formula M(L^{a})ₙ(L^{b})ₒ(L^{c})ₚ(L^{d})_{q}. Here, M is a metal having a coordination number of Q where Q is an integer selected from 2≤Q≤8, L^{a}, L^{b}, L^{c}, and L^{d} are ligands, each having a denticity of, wa, wb, w^{c} and w^{d}, respectively, and each instance of X may be selected from a various species, some of which will be discussed in the following. The subscript n, o, p, and q are independently 0, 1, 2, 3, 4, 5, 6, 7 or 8. The sum of (n·w^{a}) plus (o·w^{b}) plus (p·w^{c}) plus (q·w^{d}) is equal to Q.

In some embodiments, L^{a}, L^{b}, L^{c}, and/or L^{d}, when present, may be a monodentate ligand. Suitable monodentate ligands, unless otherwise specifically indicated, may be an alkyl or aryl species, nitrite, azide, cyanide, isocyanide (R^{a}-N≡C), nitrile (R^{a}-C≡N) , thiocyanate, carbonyl, amine (NR^{a}), aqua, hydroxy, oxo, alkoxy, phenoxy, thiol, sulfide, phosphine (P(R^{a})₃), a halide species, or a heterocyclic compound such as, but not limited to, pyridine optionally substituted with one or more of (C₁₋₆)alkyl, a halogen, nitro, hydroxy, thiol, or (C₁₋₆)alkoxy. Again, R^{a} may be selected from hydrogen, (C₁₋₆)alkyl or aryl. More preferably, L^{a}, L^{b}, L^{c}, and/or Ld are selected from methyl, isopropyl, t-butyl, cyclohexyl, phenyl, benzyl, phenylacetylenyl (-CCC₆H₅), acetate, pivalate or benzoate.

In various embodiments, L^{a}, L^{b}, L^{c}, and/or L^{d}, when present, may be a bidentate ligand. In some embodiments, the bidentate ligand is an optionally substituted hydrocarbon bound directly through carbon-metal bonds such as butane-diyl, pentane-diyl, o-xylene-diyl or acetoacetone-diyl, 2-2′-bipyridine (optionally substituted), a β-diketonate, a (C₂₋₆)dicarboxylate such as oxalate, malonate, maleate or succinate, a diamine such as ethylenediamine or propylenediamine, an imine, a chelating phosphine ligand such as bis(diphenylphosphino)ethane or bis(diphenylphosphino)methane, a phenanthroline, 8-hydroxyquinoline, a glycol such as ethylene glycol or propylene glycol, picolinic acid, 2-hydroxypyridine, pyridine-2-thiol, a dicarboxylate such as maleate, or other bidentate ligands. Preferable bidentate ligands are hydrocarbons such as pentane-diyl or orthoxylene-diyl, dicarboxylates including oxalate, malonate, maleate or succinate, and diamines such as ethylene diamine or propylene diamine.

In various embodiments, L^{a}, L^{b}, L^{c}, and/or L^{d}, when present, may be a ligand with a denticity of more than two. These ligands, in some embodiments, may be selected from diethylenetriamine, cyclopentadienyl, ethylenediaminetetraacetate, oxo, sulfide, tetraazacyclotetradecane, triaminotriethylamine, an optionally substituted SALEN compound, a polyamine such as a diamine, a triamine, or a tetramine (e.g., selected from diethylenetriamine, tetraazacyclotetradecane, triaminotriethylamine, ethylenediamine, and propylenediamine), among others.

The complex may be charge balanced by a counter ion, if necessary. In some embodiments, the photoresist precursor solution includes a nanoparticle with at least one complex described above. Suitable nanoparticles for use in the embodiments disclosed herein include organometallic or inorganic clusters containing two or more metal atoms.

The photoresist precursor solution may generally include metal atoms with appropriate organic-stabilizing ligands in an organic solvent. The photoresist precursor solution and the ultimate photoresist coating is based on metal oxide chemistry. For example, organic solutions of metal polycations with organic ligands may provide stable solutions with good resist properties. The ligands may provide radiation sensitivity, and the particular selection of ligands can influence the radiation sensitivity. In particular, the photoresist precursor solution can be designed to achieve desired levels of radiation absorption for a selected radiation based on the selection of the metal atoms as well as the associated ligands. The concentration of ligand stabilized metal atoms in the solution can be selected to provide suitable solution properties for a particular deposition approach, such as spin coating.

Preferred metals (e.g., metals that may have particular effectiveness, such as with respect to stability and processing effectiveness) are group 13, 14 and 15 metals. For example, Sn, Sb, and In may be suitable metals for formation of polynuclear metal oxo/hydroxo cations for the photoresist precursor solutions described herein. In particular, Sn may have a desirable chemistry based on organic ligands. Additional metals can also be provided to produce more complex polynuclear metal oxo/hydroxo cation formulations, including, for example, Ti, Zr, Hf, V, Co, Mo, W, Al, Ga, Si, Ge, P, As, Y, La, Ce, Lu or combinations thereof. Various metal precursor solutions have been described in U.S. Pat. Nos. 9,310,684, 9,372,402, and by Del Re et al in J. Micro/Nanolith. MEMS MOEMS 14(4), 043506 (October-December 2015), each of which are incorporated herein by reference in their entirety.

### Organic Solvent in the Photoresist Precursor Solution

In various embodiments, the photoresist precursor solution includes a solvent (e.g., before deposition and/or at the time of deposition) for dissolving the components of the composition and facilitating its coating on a substrate. Most or all of the solvent can be evaporated during the deposition operation or in a subsequent bake, for example. In general, the photoresist precursor solution may contain an organic solvent, such as alcohols, esters or combinations thereof.

The organic solvent may include various organic solvents including those conventionally used in the manufacture of electronic devices. In particular, suitable preferred solvents include, for example: aromatic compounds such as xylenes and toluene; esters such as propylene glycol monomethyl ether acetate (PGMEA), ethyl acetate (EA), and ethyl lactate (EL); alcohols such as 1-methoxy-2-propanol (PGME), 4-methyl-2-pentanol, and 1-butanol; ethers such as anisole and diisoamyl ether; ketones such as methyl ethyl ketone (MEK) and 2-heptanone; and others. In general, organic solvent selection can be influenced by solubility parameters, volatility, flammability, toxicity, viscosity and potential chemical interactions with other processing materials.

The organic solvent may also be other organic solvents. For example, the organic solvent may include aliphatic hydrocarbons such as hexane and heptane; halogenated hydrocarbons such as dichloromethane, 1,2-dichloroethane, 1-chlorohexane, and chlorobenzene; alcohols such as methanol, ethanol, 1-propanol, iso-propanol, tert-butanol, and 2-methyl-2-butanol; ethers such as propylene glycol monomethyl ether (PGME), diethyl ether, tetrahydrofuran, and 1,4-dioxane; ketones such as acetone, methyl iso-butyl ketone, 2-heptanone, and cyclohexanone (CHO); esters such as n-butyl acetate, hydroxyisobutyrate methyl ester (HBM), and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, and diphenyl carbonate; polar aprotic solvents such as dimethyl sulfoxide and dimethyl formamide; water; or any combination thereof.

The total solvent content (i.e., cumulative solvent content for all solvents) in the photoresist precursor solution is typically from 40 to 99.5 wt %, more typically from 80 to 99.5 wt %, and still more typically from 90 to 99 wt %, based on total weight of the photoresist precursor solution, for example. The desired solvent content can depend, for example, on the desired thickness of the coated photoresist layer and coating conditions.

### Binder

In some embodiments, the photoresist precursor solution also comprises a binder (e.g., a polymer binder). This binder can be a polymer or oligomer made from monomers including acrylates, methacrylates, norbornene, vinyl aromatic monomers such as styrene and p-hydroxystyrene, and combinations thereof.

### Optional Additives in the Photoresist Precursor Solution

In an embodiment, the photoresist precursor solutions described above may further include one or more additional, optional additives. For example, optional additives may include actinic and contrast dyes, anti-striation agents, plasticizers, speed enhancers, sensitizers, photo-decomposable quenchers (which is some cases may be referred to as photo-decomposable bases), basic quenchers, surfactants, and the like, or combinations thereof. If present, the optional additives can be typically present in the photoresist precursor solution in an amount from 0.01 to 10 wt %, based on total solids of the photoresist precursor solution.

### SSA Coating Composition

In embodiments, of the present disclosure, an SSA coating composition may be used to form the SSA coating over the relief pattern on the substrate. The SSA coating composition includes an SSA, which may be dissolved in a solvent, and may also include additional optional components, such as a matrix polymer and an attachment agent. The SSA coating may be deposited on the substrate as a coating, such as by spin coating, for example. One or more of the components of the SSA coating composition (such as the solvent) may be removed from the photoresist coating during various baking processes, such as an overcoat PAB.

### Solubility-Shifting Agent (SSA)

The SSA coating composition includes an SSA. In some embodiments, the SSA is dissolved in a solvent also included in the SSA overcoat. In other embodiments, the SSA may be part of a material configured to be applied to the substrate and remain substantially completely on the substrate (e.g., a material that is liquid at an elevated temperature and becomes solid or otherwise remains on the substrate after deposition). In still other embodiments, the SSA deposited as liquid, diffuses into the relief pattern as a liquid, and is rinsed away as a liquid. The SSA may also be deposited (or grown) as a solid in some embodiments.

In various embodiments, the SSA is a material that is absorbed into the relief pattern, and is absorbed into the relief pattern in response to the application of heat in some embodiments. For example, the SSA may be absorbed into the relief pattern during a substrate baking process, such as an overcoat PAB. The SSA may also be a material that binds to the relief pattern.

The SSA is configured to diffuse inward from the SSA coating and into a relief pattern formed on a substrate. The SSA is further configured to diffuse outward from the relief pattern and into an overcoat to produce a localized change in the solubility of a solubility-shifting resist included in the overcoat. In various embodiments, the SSA is an acid-based SSA, such as a free acid, a PAG (photoacid generator), or a TAG (thermal acid generator). In other embodiments, the SSA is based on a basic group or compound, such as a photobase generator (PBG) or a thermal base generator (TBG). In other embodiments, the SSA is a free ligand, such as a Lewis base. In still other embodiments, the SSA may be a photodestroyable quencher (PDQ), a crosslinker, an oxidizing agent, a reducing, agent, and others. In some embodiments, multiple SSAs may be included in the SSA coating composition. Some possible compositions of the SSA are explained in further detailed in subsequent sections.

### Solvent in the SSA Coating Composition

In various embodiments, the SSA coating composition contains an organic solvent, such as those mentioned previously. The solvent in the SSA coating composition may be any suitable solvent that does not dissolve the relief pattern.

In general, the solvent may be chosen from water, organic solvents, and mixtures thereof. In some embodiments, the solvent can include an organic-based solvent system that includes one or more organic solvents. The term “organic-based” can indicate that the solvent system includes greater than 50 wt % organic solvent based on total solvents of a given composition, more typically greater than 90 wt %, greater than 95 wt %, greater than 99 wt % or 100 wt % organic solvents, based on total solvents of the compositions. In an embodiment, a solvent component is present in an amount of from 90 to 99.75 wt % more typically from 95 to 99.5 wt % based on the composition.

Suitable organic solvents for inclusion in the SSA coating composition include, for example: alkyl esters such as alkyl acetates (e.g., 1-methoxy-2-propanol acetate), alkyl propionates (e.g., n-butyl propionate, n-pentyl propionate, n-hexyl propionate, n-heptyl propionate, ethyl lactate) and alkyl butyrates (e.g., n-butyl butyrate, isobutyl butyrate, isobutyl isobutyrate); ketones such as 2-butanone, 4-methyl-2-pentanone, 2,5-dimethyl-4-hexanone and 2,6-dimethyl-4-heptanone; aliphatic hydrocarbons such as n-heptane, n-nonane, n-octane, n-decane, 2-methylheptane, 3-methylheptane, 3,3-dimethylhexane and 2,3,4-trimethylpentane; fluorinated aliphatic hydrocarbons such as perfluoroheptane; alcohols such as straight, branched or cyclic C₄₋₉ monohydric alcohol (e.g., 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol and 4-octanol, 1-methoxy-2-propanol, 2,2,3,3,4,4-hexafluoro-1-butanol, 2,2,3,3,4,4,5,5-octafluoro-1-pentanol, 2,2,3,3,4,4,5,5,6,6-decafluoro-l-hexanol) and C5-9 fluorinated diols (e.g., 2,2,3,3,4,4-hexafluoro-1,5-pentanediol, 2,2,3,3,4,4,5,5-octafluoro-1,6-hexanediol and 2,2,3,3,4,4,5,5,6,6,7,7-dodecafluoro-1,8-octanediol); ethers such as diisopentyl ether and dipropylene glycol monomethyl ether; or mixtures containing one or more of these solvents.

In various embodiments, the solvent system further includes one or more alcohol and/or ester solvents. For certain compositions, an alcohol and/or ester solvent can provide enhanced solubility with respect to the solid components of the composition. In some embodiments, suitable alcohol solvents include, for example: straight, branched or cyclic C₄₋₉ monohydric alcohol and C₅₋₉ fluorinated diols. In an embodiment, an alcohol solvent may preferably be a C₄₋₉ monohydric alcohol, with 4-methyl-2-pentanol and 1-methoxy-2-propanol being preferred. In some embodiments, suitable ester solvents include, for example, alkyl esters having a total carbon number of from 4 to 10, with 1-methoxy-2-propanol acetate, gamma-butyrolactone and ethyl lactate being preferred. The one or more alcohol and/or ester solvents if used in a solvent system of the SSA coating composition may be present in a combined amount of from 2 to 50 wt %, more typically in an amount of from 2 to 30 wt %, based on the solvent system, for example.

In various embodiments, the solvent in the SSA coating composition may be implemented as a solvent system that includes one or more additional solvents chosen, for example, from one or more of: ketones such as 2,5-dimethyl-4-hexanone and 2,6-dimethyl-4-heptanone; and polyethers such as dipropylene glycol monomethyl ether and tripropylene glycol monomethyl ether. Such additional solvents, if used, may be present in a combined amount of from 1 to 20 wt % based on the solvent system.

### Matrix Polymer

In one or more embodiments, the SSA coating composition includes a matrix polymer. The matrix polymer is configured to have good solubility in a solvent that does not substantially dissolve the metal-based resist of the relief pattern. In various embodiments, the matrix polymer is formed from one or more monomers and may include a monomer having an ethylenically unsaturated polymerizable double bond. In some embodiments, the one or more polymers include a (meth)acrylate monomer such as isopropyl(meth)acrylate and n-butyl(meth)acrylate. In various embodiments, the one or more monomers include a vinyl-based monomer, and includes a vinyl aromatic monomer such as styrene, hydroxystyrene, vinyl naphthalene, and acenaphthylene in some embodiments. In various embodiments, the one or more monomers includes a vinyl-based monomer, such as vinyl alcohol, vinyl chloride, vinyl pyrrolidone, vinyl pyridine, vinyl amine, and vinyl acetal. In some embodiments, the one or more monomers include a maleic-based monomer such as maleic anhydride, and maleimides. In one embodiment, the one or more monomers include a norbornene-based monomer. The matrix polymer may also include any combination of the above-mentioned monomers.

### Attachment Agent

In various embodiments, the SSA coating composition includes an attachment agent. The attachment agent is configured to promote adhesion of the SSA and/or other components of the SSA coating to the relief pattern. In some embodiments, the attachment agent is a selective attachment agent that is configured to preferentially adhere to the relief pattern relative to other materials, such as exposed surfaces of substrate in openings of the relief pattern. For example, the selective attachment agent may include a chemical functional group that can be further functionalized. Some possible selective attachment agents include, but are not limited to, alcohols, silanols, amines, phosphines, phosphonic acids, and carboxylic acids. In one embodiment, the attachment agent facilitates formation of a monolayer coating on the relief pattern. In some embodiments, the attachment agent and SSA are bound together in the same molecule or complex.

### Acid as the Solubility-Shifting Agent (SSA)

In some embodiments, an SSA can be an acid that is an organic acid, which can include both non-aromatic acids and aromatic acids optionally having fluorine substitution. Suitable organic acids for an SSA of an embodiment can include: carboxylic acids and polycarboxylic acids such as alkanoic acids, including formic acid, acetic acid, propionic acid, butyric acid, dichloroacetic acid, trichloroacetic acid, perfluoroacetic acid, perfluorooctanoic acid, oxalic acid malonic acid and succinic acid; hydroxyalkanoic acids, such as citric acid; aromatic carboxylic acids such as benzoic acid, fluorobenzoic acid, hydroxybenzoic acid, and naphthoic acid; organic phosphorus acids such as dimethylphosphoric acid and dimethylphosphinic acid; and sulfonic acids such as optionally fluorinated alkylsulfonic acids including methanesulfonic acid, trifluoromethanesulfonic acid, ethanesulfonic acid, 1-butanesulfonic acid, 1-perfluorobutanesulfonic acid, 1,1,2,2-tetrafluorobutane-1-sulfonic acid, 1,1,2,2-tetrafluoro-4-hydroxybutane-1-sulfonic acid, 1-pentanesulfonic acid, 1-hexanesulfonic acid, and 1-heptanesulfonic acid; or any combination thereof, for example.

In some embodiments, an SSA can be an aromatic sulfonic acid. For example, an aromatic sulfonic acid can be of general Formula 4:

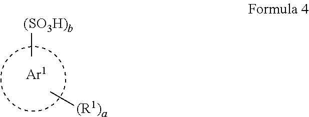

In Formula 4, Ar¹ can represent an aromatic group, which can be carbocyclic, heterocyclic, or a combination thereof. The aromatic group can be monocyclic, for example, phenyl or pyridyl, or polycyclic, for example biphenyl, and can include: plural fused aromatic rings such as naphthyl, anthracenyl, pyrenyl, or quinolinyl; or fused ring systems having both aromatic and non-aromatic rings such as 1,2,3,4-tetrahydronaphthalene, 9,10-dihydroanthracene or fluorene. A wide variety of aromatic groups may be used for Ar¹. The aromatic group typically can have from 5 to 40 carbons, preferably from 6 to 35 carbons, and more preferably from 6 to 30 carbons. Suitable aromatic groups can include, but are not limited to: phenyl, biphenyl, naphthalenyl, anthracenyl, phenanthrenyl, pyrenyl, tetracenyl, triphenylenyl, tetraphenyl, benzo[f]tetraphenyl, benzo[m]tetraphenyl, benzo[k]tetraphenyl, pentacenyl, perylenyl, benzo[a]pyrenyl, benzo[e]pyrenyl, benzo[ghi]perylenyl, coronenyl, quinolonyl, 7,8-benzoquinolinyl, fluorenyl, and 12H-dibenzo[b,h]fluorenyl. Of these, phenyl can be particularly preferred.

In Formula 4, R¹ independently can represent a halogen atom, hydroxy, substituted or unsubstituted alkyl, substituted or unsubstituted heteroalkyl, substituted or unsubstituted carbocyclic aryl, substituted or unsubstituted heterocyclic aryl, substituted or unsubstituted alkoxy, or a combination thereof. R¹ can also include one or more groups such as ester, carboxy, ether, or a combination thereof.

In Formula 4, “a” can represent an integer of 0 or more and “b” can represent an integer of 1 or more, provided that a+b is not greater than the total number of available aromatic carbon atoms of Ar¹. Preferably, two or more of R¹ can be independently a fluorine atom or a fluoroalkyl group bonded directly to an aromatic ring carbon atom.

The aromatic acid can be a sulfonic acid including a phenyl, biphenyl, naphthyl, anthracenyl, thiophene or furan group. The aromatic acid can be chosen from one or more aromatic sulfonic acids of the following general Formulas 5-10:

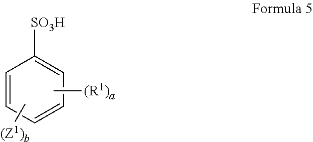

In Formula 5, R¹ can independently represent a substituted or unsubstituted C1-C20 alkyl group, a substituted or unsubstituted C5-C20 aryl group, or a combination thereof, optionally containing one or more group chosen from carbonyl, carbonyloxy, sulfonamido, ether, thioether, a substituted or unsubstituted alkylene group, or a combination thereof.

In Formula 5, Z¹ can independently represent a group chosen from carboxyl, hydroxy, nitro, cyano, C1 to C5 alkoxy, formyl and sulfonic acid. In Formula 5, “a” and “b” can be independently an integer from 0 to 5, and a+b can be 5 or less.

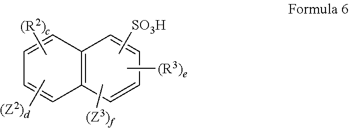

In Formula 6, R² and R³ each can independently represent a substituted or unsubstituted C1-C20 alkyl group, a substituted or unsubstituted C5-C16 aryl group, or a combination thereof, optionally containing one or more group chosen from carbonyl, carbonyloxy, sulfonamido, ether, thioether, a substituted or unsubstituted alkylene group, or a combination thereof.

In Formula 6, Z² and Z³ each can independently represent a group chosen from carboxyl, hydroxy, nitro, cyano, C1 to C5 alkoxy, formyl and sulfonic acid. In Formula 6, “c” and “d” can be independently an integer from 0 to 4, c+d can be 4 or less, “e” and “f” can be independently an integer from 0 to 3, and e+f can be 3 or less.

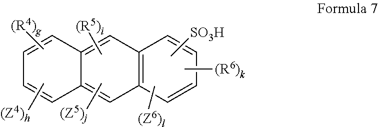

In Formula 7, R⁴, R⁵ and R⁶ each can independently represent a substituted or unsubstituted C1-C20 alkyl group, a substituted or unsubstituted C5-C12 aryl group, or a combination thereof, optionally containing one or more group chosen from carbonyl, carbonyloxy, sulfonamido, ether, thioether, a substituted or unsubstituted alkylene group, or a combination thereof.

In Formula 7, Z⁴, Z⁵ and Z⁶ each can independently represent a group chosen from carboxyl, hydroxy, nitro, cyano, C1 to C5 alkoxy, formyl and sulfonic acid. In Formula 7, “g” and “h” can be independently an integer from 0 to 4, g+h can be 4 or less, “i” and “j” can be independently an integer from 0 to 2, i+j can be 2 or less, “k” and “1” can be independently an integer from 0 to 3, and k+1 can be 3 or less.

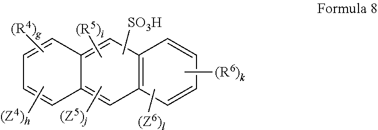

In Formula 8, R⁴, R⁵ and R⁶ each can independently represent a substituted or unsubstituted C1-C20 alkyl group, a substituted or unsubstituted C5-C12 aryl group, or a combination thereof, optionally containing one or more group chosen from carbonyl, carbonyloxy, sulfonamido, ether, thioether, a substituted or unsubstituted alkylene group, or a combination thereof.

In Formula 8, Z⁴, Z⁵ and Z⁶ each can independently represent a group chosen from carboxyl, hydroxy, nitro, cyano, C1 to C5 alkoxy, formyl and sulfonic acid. In Formula 8, “g” and “h” can be independently an integer from 0 to 4, g+h can be 4 or less, “i” and “j” can be independently an integer from 0 to 1, i+j can be 1 or less, “k” and “1” can be independently an integer from 0 to 4, and k+l can be 4 or less.

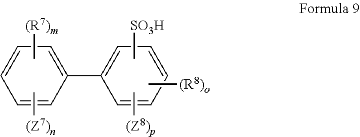

In Formula 9, R⁷ and R⁸ each can independently represent a substituted or unsubstituted C1-C20 alkyl group, a substituted or unsubstituted C5-C14 aryl group, or a combination thereof, optionally containing one or more group chosen from carboxyl, carbonyl, carbonyloxy, sulfonamido, ether, thioether, a substituted or unsubstituted alkylene group, or a combination thereof.

In Formula 9, Z⁷ and Z⁸ each can independently represent a group chosen from hydroxy, nitro, cyano, C1 to C5 alkoxy, formyl and sulfonic acid. In Formula 9, “m” and “n” can be independently an integer from 0 to 5, m+n can be 5 or less, “o” and “p” can be independently an integer from 0 to 4, and o+p can be 4 or less.

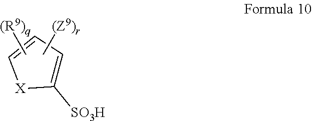

In Formula 10, X can be O or S. In Formula 10, R⁹ can independently represent a substituted or unsubstituted C1-C20 alkyl group, a substituted or unsubstituted C5-C20 aryl group, or a combination thereof, optionally containing one or more group chosen from carbonyl, carbonyloxy, sulfonamido, ether, thioether, a substituted or unsubstituted alkylene group, or a combination thereof.

In Formula 10, Z⁹ can independently represent a group chosen from carboxyl, hydroxy, nitro, cyano, C1 to C5 alkoxy, formyl and sulfonic acid. In Formula 10, “q” and “r” can be independently an integer from 0 to 3, and q+r can be 3 or less.

For each of the structures of Formulas 5-10, the R¹-R⁹ groups can optionally form a fused structure together with their respective associated rings, for example.

For an SSA of an embodiment, example aromatic sulfonic acids can include, without limitation, the following:

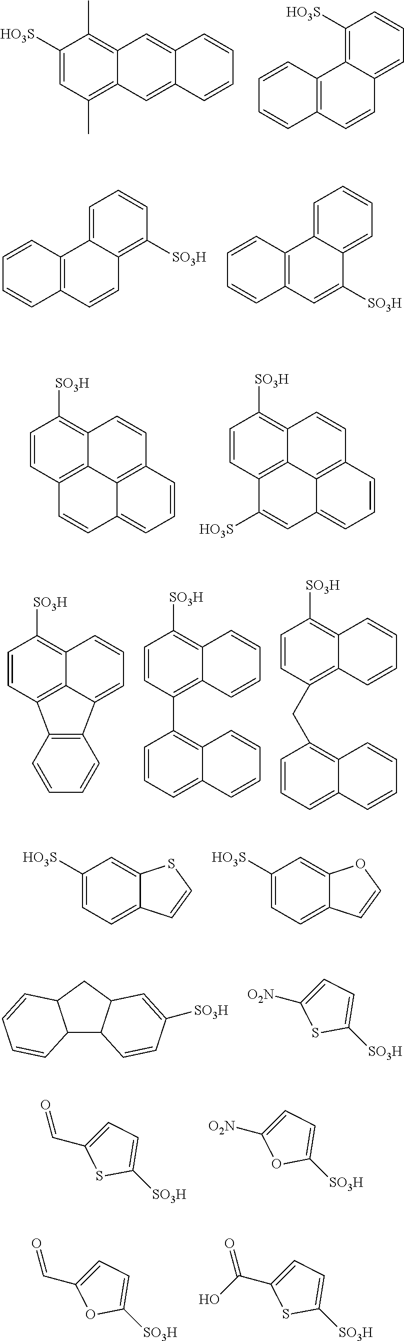

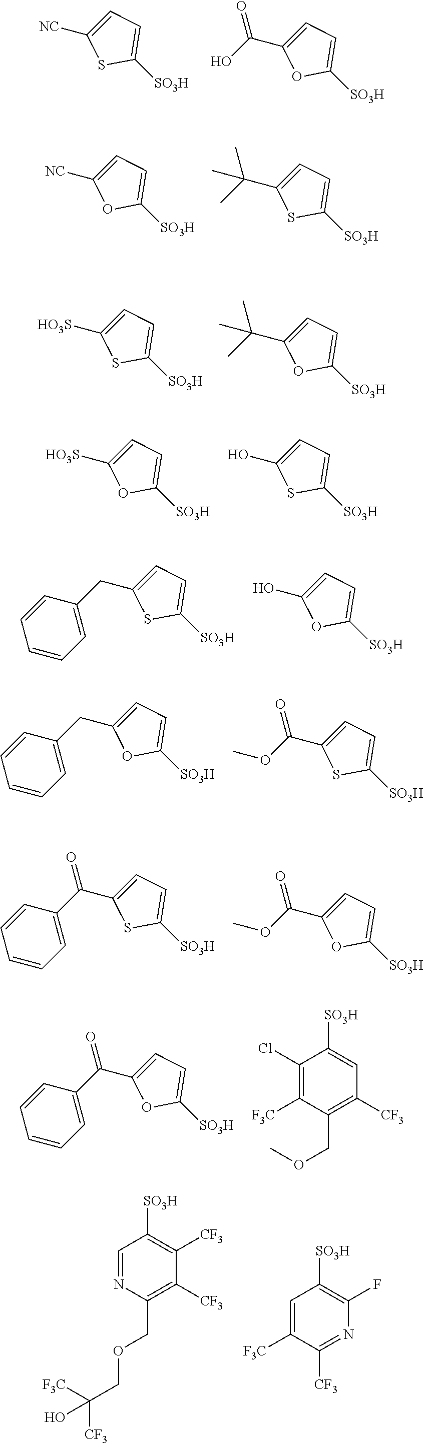

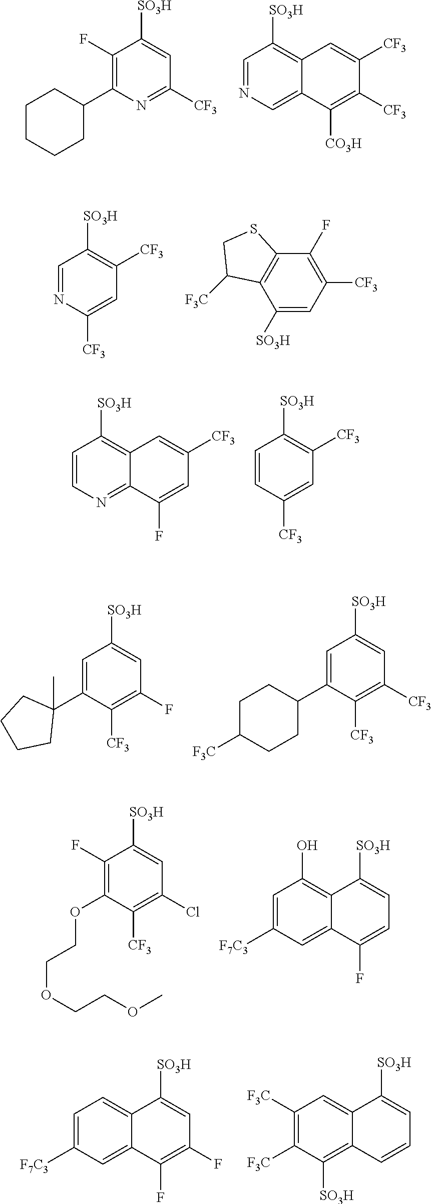

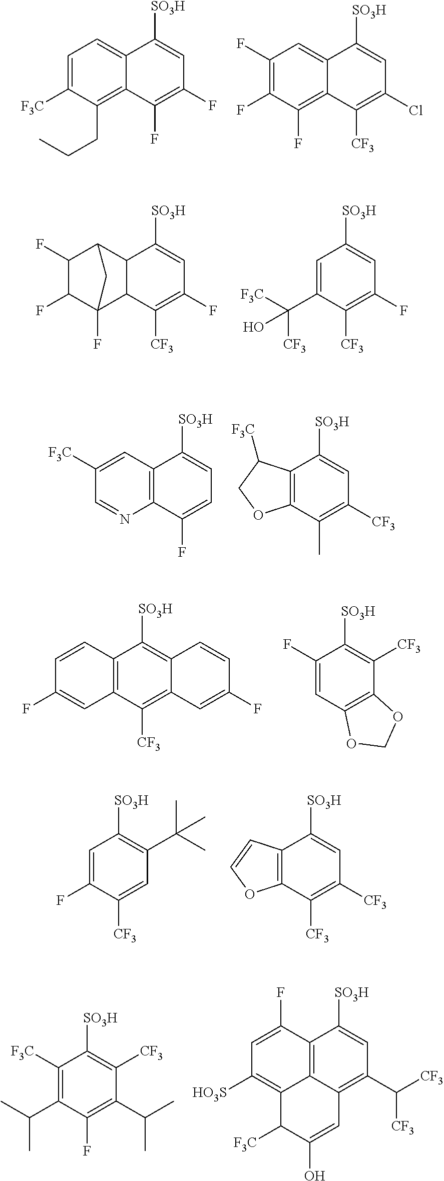

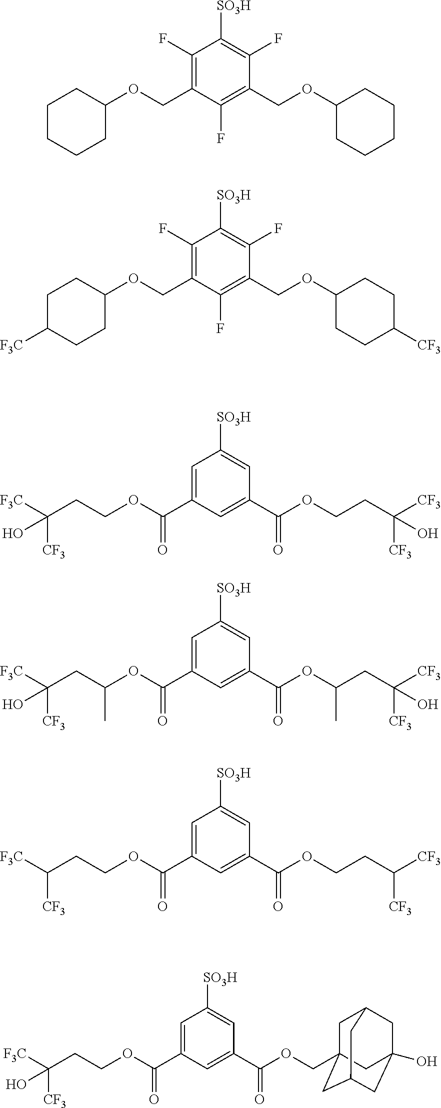 [SMILES: O=S(=O)(O)c1c(F)c(COC2CCCCC2)c(F)c(COC2CCCCC2)c1F ; O=S(=O)(O)c1c(F)c(COC2CCC(C(F)(F)F)CC2)c(F)c(COC2CCC(C(F)(F)F)CC2)c1F ; O=C(OCCC(O)(C(F)(F)F)C(F)(F)F)c1cc(C(=O)OCCC(O)(C(F)(F)F)C(F)(F)F)cc(S(=O)(=O)O)c1 ; CC(CC(O)(C(F)(F)F)C(F)(F)F)OC(=O)c1cc(C(=O)OC(C)CC(O)(C(F)(F)F)C(F)(F)F)cc(S(=O)(=O)O)c1 ; O=C(OCCC(C(F)(F)F)C(F)(F)F)c1cc(C(=O)OCCC(C(F)(F)F)C(F)(F)F)cc(S(=O)(=O)O)c1 ; O=C(OCCC(O)(C(F)(F)F)C(F)(F)F)c1cc(C(=O)OCC23CC4CC(CC(O)(C4)C2)C3)cc(S(=O)(=O)O)c1]

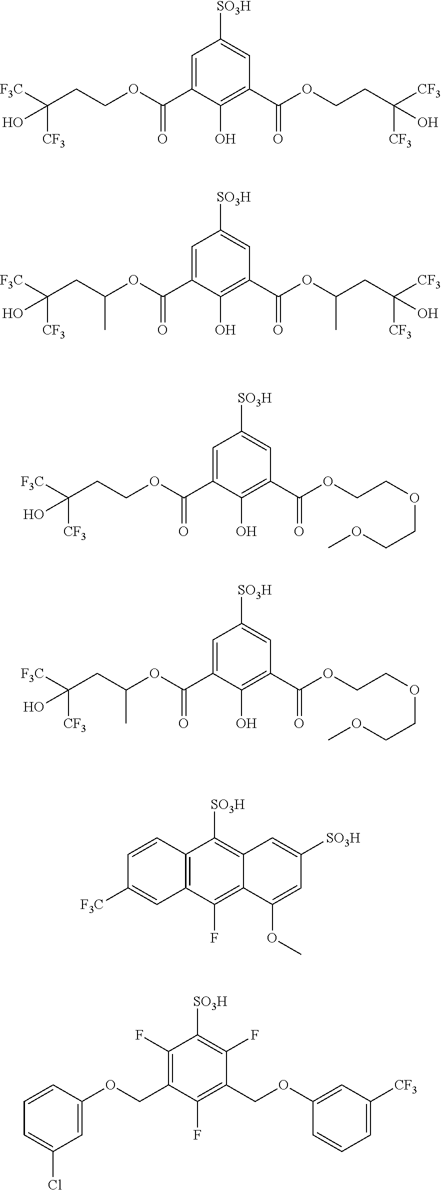 [SMILES: O=C(OCCC(O)(C(F)(F)F)C(F)(F)F)c1cc(S(=O)(=O)O)cc(C(=O)OCCC(O)(C(F)(F)F)C(F)(F)F)c1O ; CC(CC(O)(C(F)(F)F)C(F)(F)F)OC(=O)c1cc(S(=O)(=O)O)cc(C(=O)OC(C)CC(O)(C(F)(F)F)C(F)(F)F)c1O ; COCCOCCOC(=O)c1cc(S(=O)(=O)O)cc(C(=O)OCCC(O)(C(F)(F)F)C(F)(F)F)c1O ; COCCOCCOC(=O)c1cc(S(=O)(=O)O)cc(C(=O)OC(C)CC(O)(C(F)(F)F)C(F)(F)F)c1O ; COc1cc(S(=O)(=O)O)cc2c(S(=O)(=O)O)c3ccc(C(F)(F)F)cc3c(F)c12 ; O=S(=O)(O)c1c(F)c(COc2cccc(Cl)c2)c(F)c(COc2cccc(C(F)(F)F)c2)c1F]

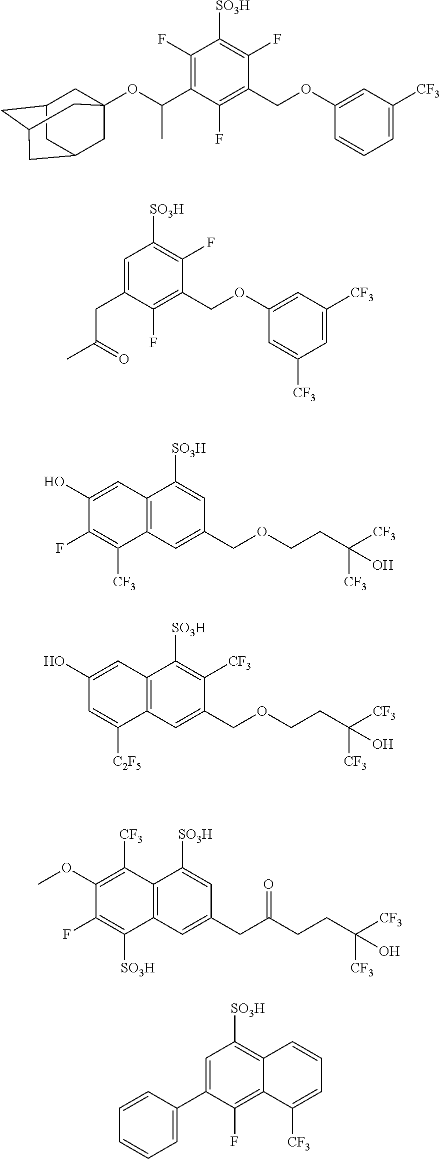

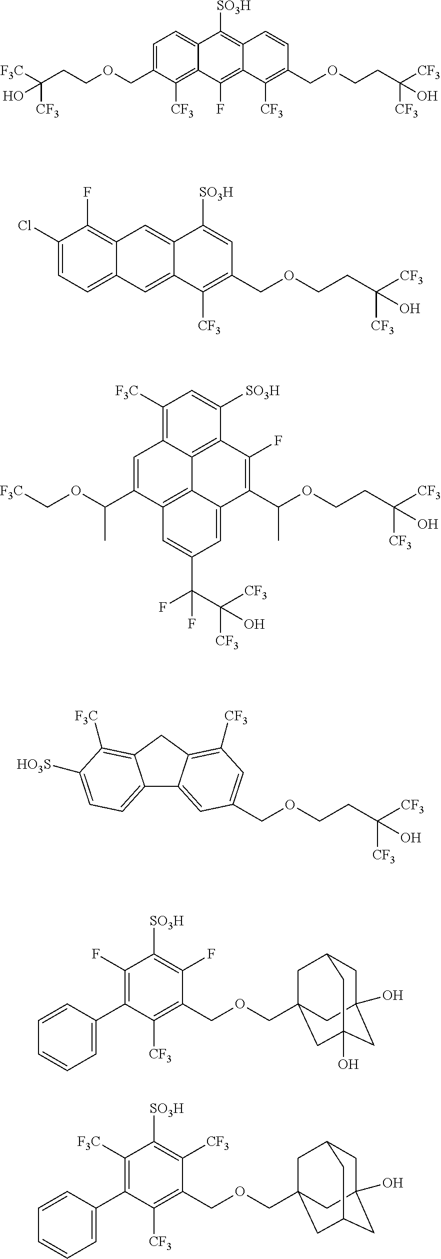

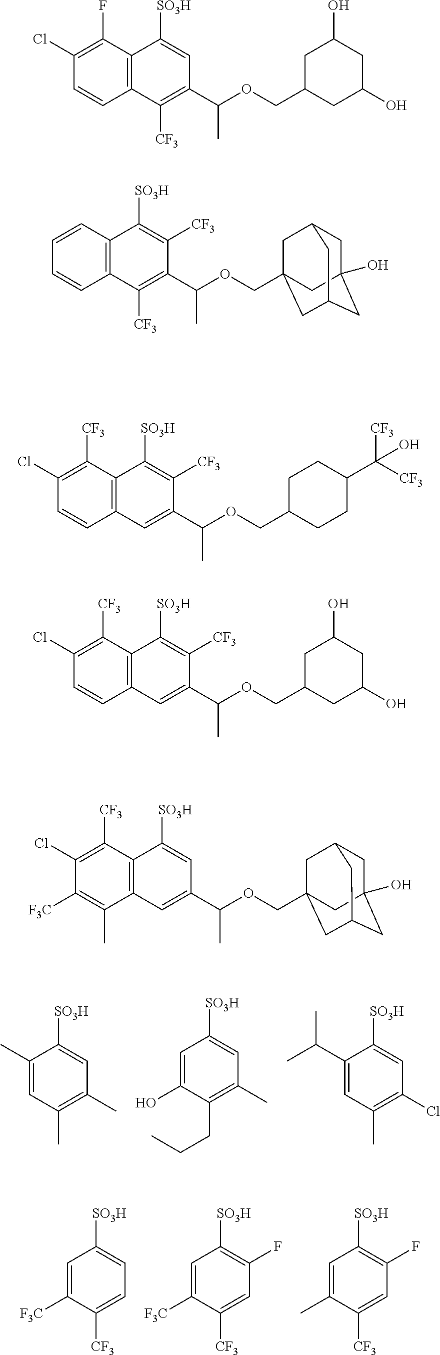

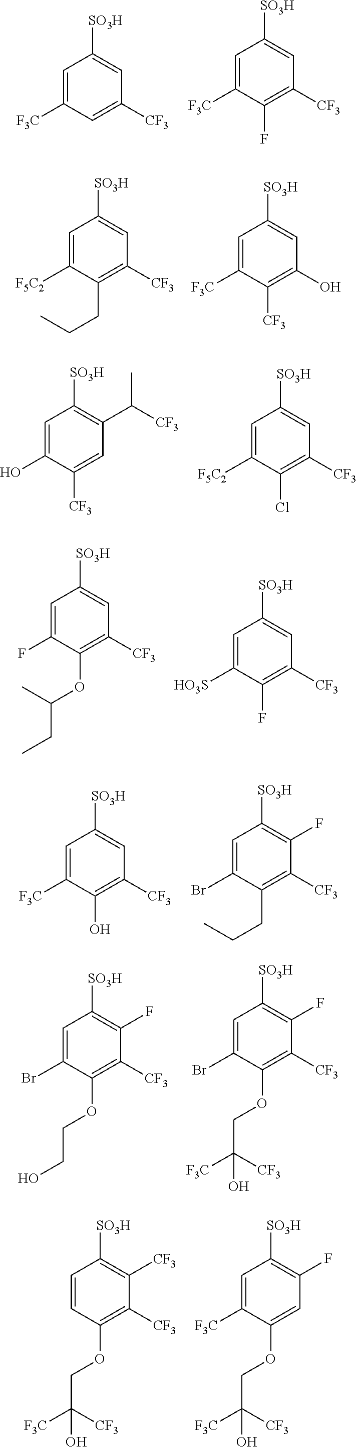

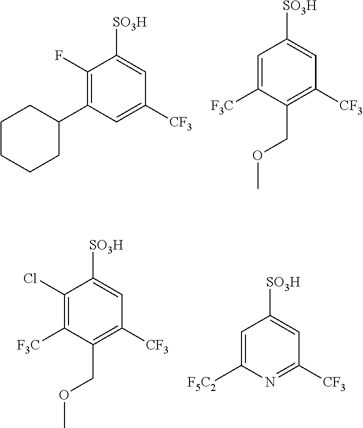

For an SSA of an embodiment, example non-aromatic sulfonic acids can include. without limitation, the following:

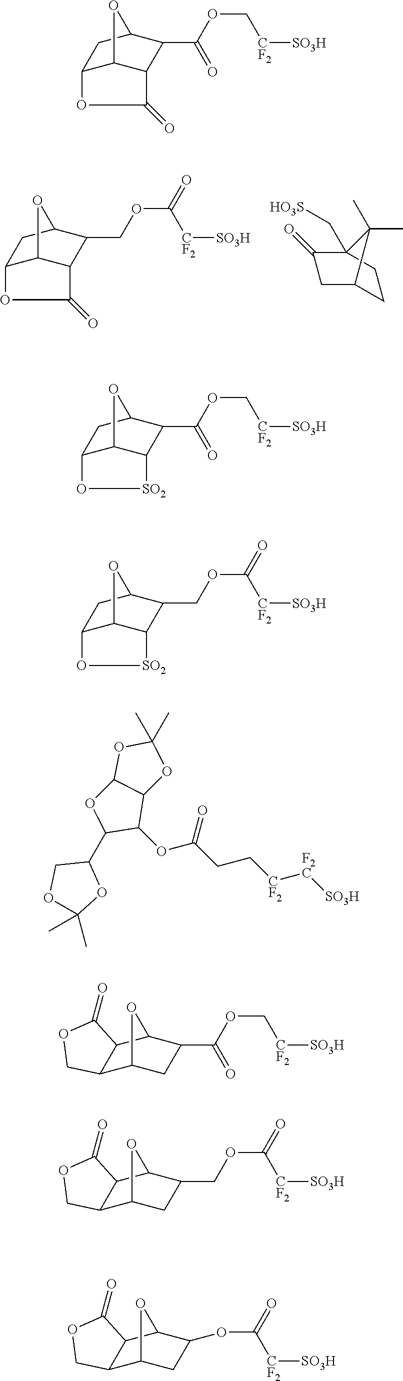

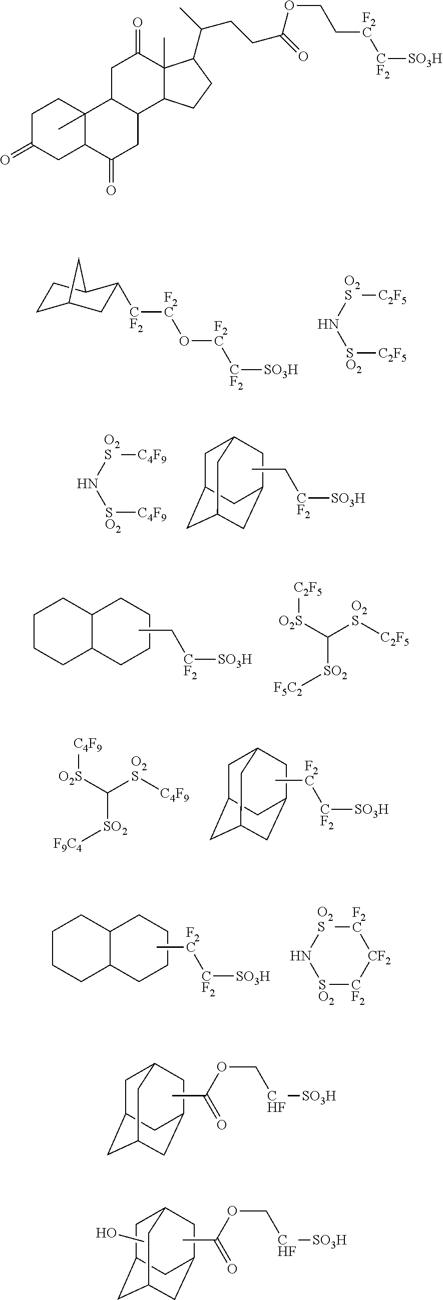

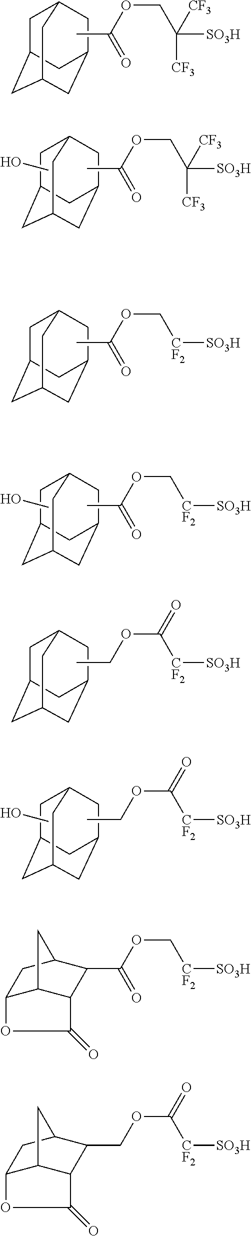

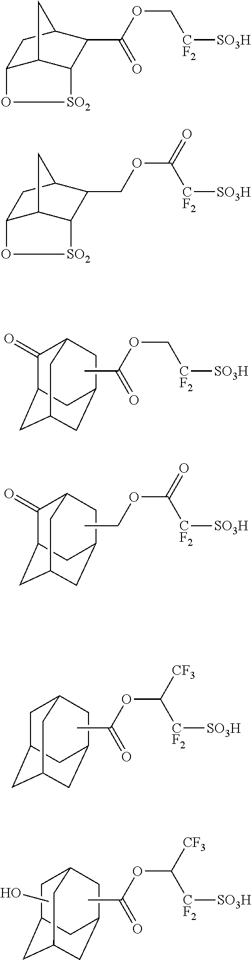

### Photoacid Generator (PAG) as the Solubility-Shifting Agent (SSA)

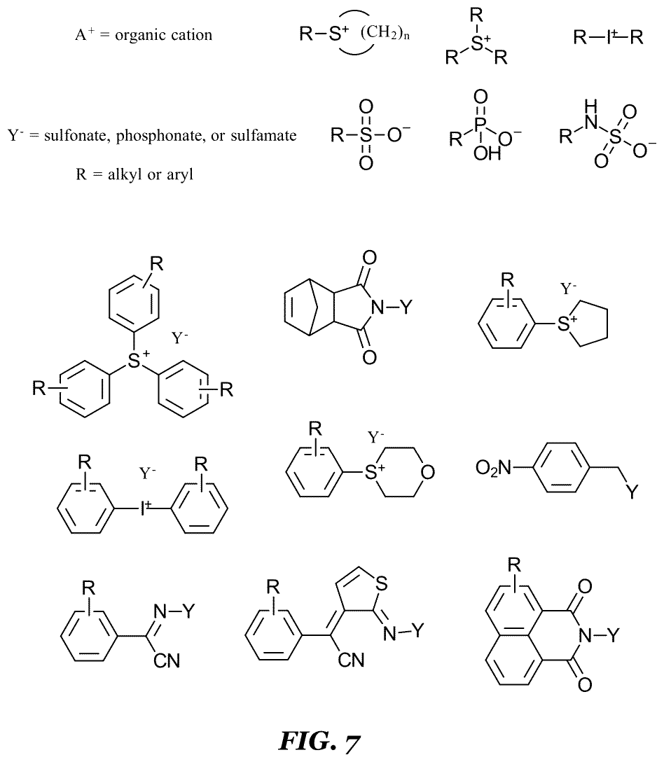

Some non-limiting examples of particular PAGs having the formula A⁺Y⁻ that may be used as the SSA are shown in FIG. 7. Here, A⁺ is a cation with at least one R group and an element selected from a group consisting sulfur, iodine, nitrogen, and combinations thereof, the R group being an alkyl group, an aryl group, or norbornene, some examples of which are shown in the structures in FIG. 7. Meanwhile, Y⁻ is an anion selected from a group consisting of an organic sulfonate ion, an organic phosphonate ion, and an organic sulfamate ion.

### Thermal Acid Generator (TAG) as the Solubility-Shifting Agent (SSA)

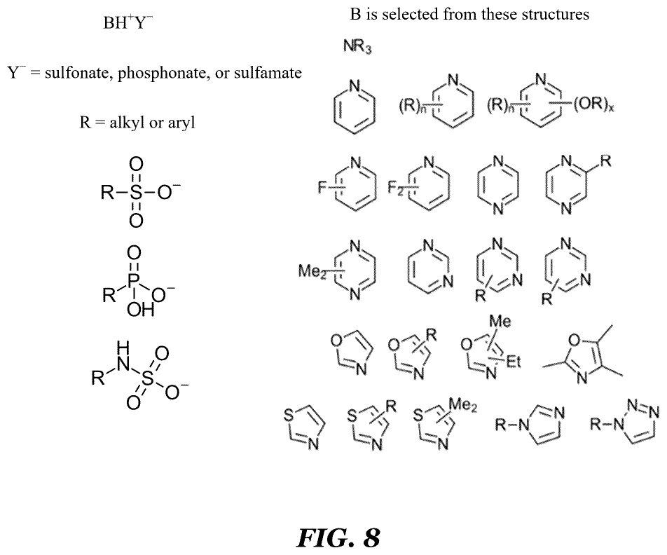

Some non-limiting examples of particular TAGs having the formula BH+Y that may be used as the SSA are shown in FIG. 8. Here, BH⁺ is a positive ion having hydrogen and a species B selected from a group consisting of NR₃ with R being similar or different alkyl or aryl groups, a substituted benzene compound including nitrogen, and a substituted cyclopentadiene compound including nitrogen, some examples of which are shown in the structures in FIG. 8. Again, Y⁻ is an anion selected from a group consisting of an organic sulfonate ion, an organic phosphonate ion, and an organic sulfamate ion. Additionally, it should be noted that BH⁺Y⁻ may be a specific example of an SSA having the formula A⁺Y⁻ where A⁺=BH⁺.

### Base as the Solubility-Shifting Agent (SSA)

Some non-limiting examples of particular bases that may be suitable for use as the SSA are hydroxides, carboxylates, amines, imines, amides, and mixtures thereof. For example, the SSA may be or include a base that may be used in a photoresist material. Specific examples of bases include ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, tetraethylammonium phosphate, and combinations thereof. Various bases have been described in International Publication WO 2023/028243, which is incorporated by reference in its entirety.

### Photobase Generator (PBG) as the Solubility-Shifting Agent (SSA)

PBGs suitable for use as the SSA be any compound that can release a base in response to applied radiation (e.g., actinic radiation), and is not specifically limited. The PBG is configured to remain inactive under processing conditions prior to its use as an SSA, but can release a basic species once externally stimulated. The PBG may be exemplified as ionic compounds whose base components may be neutralized by forming a salt, such as a transition metal complex compound, those having an ammonium salt structure, those having an amidine moiety combined with carboxylic acid to form a salt, as well as nonionic compounds whose base components are hidden in a latent form, (e.g., through urethane bond or oxime bond of carbamate derivative, oxime ester derivative, or acyl compound). Various PBGs have been described in U.S. Pat. Nos. 10,450,417 and 8,703,404, which are incorporated by reference in their entirety.

### Thermal Base Generator (TBG) as the Solubility-Shifting Agent (SSA)

TBGs suitable for use as the SSA may form a base upon heating above a first temperature, (e.g., about 120° C. or higher, but any other temperatures are possible). The TBG may include a functional group such as an amide, sulfonamide, imide, imine, O-acyl oxime, benzoyloxycarbonyl derivative, quarternary ammonium salt, nifedipine, carbamate, or combinations thereof, for example. Various TBGs have been described in International Publication WO 2023/028243 and U.S. Patent Publication 2015/0346599, which are incorporated by reference in their entirety.

Some specific examples of suitable TBGs include:
0-{β-(dimethylamino)ethyl)aminocarbonyl}benzoic acid,
0-{(γ-(dimethylamino)propyl)aminocarbonyl}benzoic acid,
2,5-bis{(β-(dimethylamino)ethyl)aminocarbonyl} terephthalic acid,
2,5-bis{(γ-(dimethylamino)propyl)aminocarbonyl} terephthalic acid,
2,4-bis{(β-(dimethylamino)ethyl)aminocarbonyl} isophthalic acid,
2,4-bis{(γ-(dimethylamino)propyl)aminocarbonyl} isophthalic acid, or combinations thereof, for example.

### Photo-Destroyable Quencher (PDQ) as the Solubility-Shifting Agent (SSA)

A PDQ can generate a weak acid upon irradiation. The acid generated from a PDQ may be not strong enough to react rapidly with acid-labile groups or other solubility shifting groups that are present in the relief pattern. However, in regions where the PDQ is not exposed to radiation, the PDQ is able to quench a strong acid via an anion exchange mechanism rendering it unable to react with acid-labile, solubility-shifting groups. Example PDQs can include, for example, include photo-decomposable cations, and can be preferably include those also useful for preparing strong acid generator compounds paired with an anion of a weak acid (pKₐ>−1) such as, for example, an anion of a C₁₋₂₀ carboxylic acid or a C₁₋₂₀ sulfonic acid.

Example carboxylic acids can include formic acid, acetic acid, propionic acid, tartaric acid, succinic acid, cyclohexanecarboxylic acid, benzoic acid, salicylic acid, and the like. Example sulfonic acids can include p-toluene sulfonic acid, camphor sulfonic acid and the like. In some embodiments, the PDQ can be a photo-decomposable organic zwitterion compound such as diphenyliodonium-2-carboxylate.

### Crosslinker as SSA

Crosslinking SSAs could for example be dehydrating agents that cause condensation in metal-based resists and metal based resist solubility-shiftable overcoats. Some non-limiting examples include ortho esters such as methyl orthoformate, ethyl orthoformate, methyl orthoacetate and ethyl orthoacetate.

### Oxidizing Agent as SSA

Metal-based resists are known in the art to oxidize during exposure to EUV, exposure to air (and moisture) and during baking steps. The longer the resist film is exposed to air and the longer and higher temperature of the bake, the greater the extent of oxidation. This oxidation can manifest as a reduction in a resist's organic developer solubility. Some non-limiting oxidizing agents useful as SSAs are hydroperoxides such as tert-butyl hydroperoxide, cumyl hydroperoxide and ethylbenzenehydroperoxide; organic peroxides such as di-tert-butyl peroxide, dicumyl peroxide, prostaglandin G2 and methyl ethyl ketone peroxide; peroxyacids such as m-chloroperoxybenzoic acid, tert-butyl peroxybenzoate and dibenzoyl peroxide; quinones such as ortho-benzoquinone, para-benzoquinone, para-quinone methide, ortho-quinone methide, chloranil and fluoranil; halogenating agents such as Selectfluor, n-bromosuccinamide, trichloroisocyanuric acid and tribromoisocyanuric acid. Preferred oxidants include di-tert-butyl peroxide, dicumyl peroxide, tert-butyl peroxybenzoate, parabenzoquinone and chloranil.

### Reducing Agent as SSA

Reducing agents are also suitable SSAs as they may prevent oxidation or even cause a reduction reaction that increases the solubility of the metal-based resist overcoat. Some non-limiting examples of suitable SSA reducing agents are phenols such as phenol, polyphenols, catechol, 4-tert-butyl catechol, hydroquinone and butylated hydroxytoluene (BHT); ascorbic acid; glutathione; reducing sugars such as glucose, fructose, lactose and maltose; benzyl alcohol; benzaldehyde; phosphines such as triphenyl phosphine and tris (2-carboxyethyl) phosphine. Preferred reducing agents include phenols such as phenol, polyphenol, hydroquinone and BHT.

### Free ligands as SSA

In some embodiments, the SSA is a free ligand. Free ligands that are suitable for use as the SSA may be configured to alter the solubility of a metal-based resist overcoat. In some embodiments, the metal-based resist is a negative-tone resist. Many negative-tone resists function by a condensation mechanism. During exposure, photosensitive ligands are removed from the complex leaving behind active sites and changing the solubility of the film. During a post-exposure bake (PEB) these active sites on the metal complex undergo condensation reactions with neighboring complexes resulting in a crosslinked network with greatly reduced solubility. For example, a negative-tone metal-based resist's solubility in organic developers such as n-butyl acetate and 2-heptanone is known to decrease with extent of condensation. Ligands that prevent such condensation are suitable SSAs.

In some embodiments the free ligand is a Lewis base. Suitable Lewis base ligands include alcohols such as glycerol, phenol, dihydroxybenzenes, polyhydroxystyrene (or copolymers thereof) and polyvinylalcohol (or copolymers thereof), ethers such as anisole, polyethylene glycol and polypropylene glycol, ketones, sodium, potassium or ammonium salts of (C₄₋₁₂)carboxylic acids such as butyrate, caproate and laurate, sodium, potassium or ammonium salts of (C₂₋₁₂)dicarboxylic acids such as oxalate, malonate, maleate or succinate, polycarboxylates such as (meth)acrylates (and copolymers thereof), sulfonates such as p-toluenesulfonate, dodecylbezenesulfonate, ethane-1,2-disulfonate, butane-1,4-disulfonate, benzene-1,4-disulfonate. Other suitable Lewis base ligands include those described in the quencher section of the polymer-based overcoat particularly the amines, amides, imides and carbamates.

In some embodiments the free ligand is a Lewis acid. Suitable Lewis acid ligands include alcohols such as glycerol, phenol, dihydroxybenzenes, polyhydroxystyrene (or copolymers thereof) and polyvinylalcohol (or copolymers thereof), (C₄₋₁₂carboxylic acids such as butyric acid, caproic acid and lauric acid, (C₂₋₁₂)dicarboxylic acids such as oxalic acid, malonic acid, maleic acid, tartaric acid or succinic acid, polycarboxylic acids such as (meth) acrylic acid (and copolymers thereof), sulfonic acids such as p-toluenesulfonic acid, dodecylbezenesulfonic acid, ethane-1,2-disulfonic acid, butane-1,4-disulfonic acid, benzene-1,4-disulfonic acid.

### Overcoat Composition

In embodiments of the present disclosure, an overcoat composition may be used to form the overcoat deposited in openings of the relief pattern on the substrate. The overcoat composition includes a solubility-shiftable composition (e.g., a solubility-shiftable resist) and may optionally include other components, such as a solvent and/or a binder.

### Solubility-Shiftable Composition

The solubility shiftable composition is generally a composition that can undergo a change in solubility when exposed to a solubility-shifting agent. In one embodiment, the solubility-shiftable composition is a solubility-shiftable resist that includes an organometallic material (e.g., a metal-based resist). In another embodiment, the solubility-shiftable composition is a solubility-shiftable resist that includes a polymer that contains a deprotectable monomer sensitive to the solubility-shifting agent (e.g., a polymer-based resist). For example, a polymer that contains an acid-deprotectable pendant group, such as a tertiary ester is useful when the SSA is an acid or acid generator. In another embodiment, the solubility shiftable composition may be a polymer with cleavable groups in its backbone (which may be referred to as “backbone degradable polymers”). In still another embodiment, the solubility shiftable composition includes a developable bottom anti-reflective coating (dBARC). In another embodiment, the solubility shiftable composition includes a reversible crosslinked material that is not a dBARC.

The solubility shiftable composition may be composed of polymers or oligomers. The polymer/oligomer may be made from monomers including acrylates, methacrylates, norbornene, vinyl aromatic monomers such as styrene and p-hydroxystyrene, and combinations thereof. In other embodiments, the solubility shiftable composition comprises an organometallic or inorganic material. When coated as the overcoat, the solubility-shiftable composition is processed such that it becomes insoluble in a developer except in regions treated with the solubility shifting agent, which remain soluble in the developer.

### Metal-Based Resist in the Overcoat Composition

The solubility-shiftable composition may include a metal-based resist, such as selected from any of those described above with respect to the photoresist precursor solution. In some embodiments, the metal-based resist included in the overcoat composition is photoactive (e.g., by including one or more ligands, or through other mechanisms). In other embodiments, the metal-based resist in the overcoat composition is similar to the metal-based resist in the photoresist precursor solution, but is not photoactive (e.g., ligands providing photoactivity may be replaced with other ligands, such as ligands providing the solubility-shiftable functionality). In some embodiments, the metal-based resist in the overcoat composition is similar to the metal-based resist in the photoresist precursor solution, but is thermally active (e.g., ligands providing photoactivity may be replaced by ligands that are thermally active). Thermally active ligands may decompose or dissociate from the complex thereby changing the solubility directly or leaving behind active sites that participate in condensation, reaction with the SSA or other solubility change mechanisms. In still other embodiments, the metal-based resist in the overcoat composition is selected from those described above, but is substantially different from the metal-based resist in the photoresist precursor solution, such as having substantially different ligands or a different metal.

### Polymer-Based Resist in the Overcoat Composition

The solubility-shiftable composition may include a polymer-based resist. The polymer-based resist may be a homopolymer or a copolymer having a plurality of distinct repeat units (also referred to as monomers), for example, two, three, four, or more distinct repeat units. The polymer-based resist may include a polymer composed of monomers including vinyl monomers such as styrene, acrylate, methacrylate, norbornene, or combinations thereof, as well as other monomers that can be polymerized into a polymer. The repeat units of the polymer may all be formed from (meth)acrylate monomers, all be formed from (vinyl) aromatic monomers, or all be formed from (meth)acrylate monomers and (vinyl) aromatic monomers, for example.

The polymer may include one or more monomers with reactive functional groups. In one embodiment, the polymer of the polymer-based resist includes an ester functional group that can react with an acid so that it is converted into a carboxylic acid functional group (e.g., shifting the solubility of the material, such as allowing dissolution in an aqueous base, such as aqueous TMAH, for example). In another embodiment the polymer of the polymer-based resist includes an ester functional group that will not deprotect in the presence of a quencher SSA, but deprotects elsewhere (e.g., shifting the solubility of the material, such as allowing dissolution of the solubility-shifted region in an organic solvent such as 2-heptanone or n-butyl acetate for example). In some embodiments, the reactive functional group includes a hydroxy-aryl group. In some embodiments, the polymer includes para-hydroxystyrene. In some embodiments, the polymer includes a carboxylic acid functionality, such as acrylic acid or methacrylic acid.

Polymers included in the polymer-based resist may have a repeating unit having an alicyclic hydrocarbon structure and/or an aromatic ring structure that does not have a reactive functional group. In some embodiments, the polymer includes one or more monomers of Formula 1:

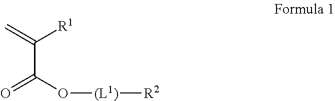

In Formula 1, R¹ may be hydrogen, fluorine, cyano, substituted or unsubstituted C₁₋₁₀ alkyl, or substituted or unsubstituted C₁₋₁₀ fluoroalkyl. In Formula 1, R² may be hydrogen, fluorine, or substituted or unsubstituted C₁₋₅ alkyl, typically methyl. In Formula 1, L¹ may be a single bond or a divalent linking group. For example, L¹ may be a single bond or a divalent linking group including one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₁₋₃₀ heterocycloalkylene, substituted or unsubstituted C₆₋₃₀ arylene, or substituted or unsubstituted C₄₋₃₀ heteroarylene. L¹ may optionally can further include one or more groups chosen, for example, from —O—, —C(O)—, —C(O)—O—, —S—, —S(O)₂—, and —N(R³)—S(O)₂—, where R³ can be hydrogen, substituted or unsubstituted C₁₋₂₀ alkyl, substituted or unsubstituted C₃₋₂₀ cycloalkyl, or substituted or unsubstituted C₁₋₂₀ heterocycloalkyl. In Formula 1, R² may also be a monocyclic, polycyclic, or fused polycyclic C₄₋₂₀ lactone-containing group, or a monocyclic, polycyclic, or fused polycyclic C₄₋₂₀ sultone-containing group.

The form the polymer can be any form of a random type, a block type, a comb type, and a star type. When the polymer includes more than one type of repeat unit, it can take the form of a random copolymer. The polymer may be synthesized, for example, by polymerization of radicals, cations, or anions of an unsaturated monomer, corresponding to each structure. In various embodiments, it is possible to obtain a target resin by using an unsaturated monomer corresponding to a precursor of each structure to perform polymerization, and then performing a polymer reaction.

The polymer may be synthesized and purified by any suitable method (e.g., radical polymerization). Example synthesis and purification methods that can be suitable are described in paragraphs 0201 to 0202 of Japanese Patent Application Laid-Open No. 2008-292975, for example. The weight average molecular weight of the polymer may be 7,000 or more, such as in a range of 7,000 to 200,000, in a range of 7,000 to 50,000, in a range of 7,000 to 40,000, or in a range of 7,000 to 30,000, in terms of polystyrene by a Gel Permeation Chromatography (GPC) method, for example. If the weight average molecular weight is less than 7,000, the solubility in an organic developer may undesirably become higher, causing concern that a fine pattern cannot be formed or cannot be formed according to a desired manufacturing specification.

Usually, the polydispersity (molecular weight distribution) of the polymer is in a range of 1.0 to 3.0, in a range of 1.0 to 2.6, in a range of 1.0 to 2.0, or in a range of 1.1 to 1.6, for example. Generally, the smaller the molecular weight distribution is, the better the resolution and resist shape can be, and the smoother the side wall of the resist pattern can be.

### Solvent in the Overcoat Composition

In various embodiments, the overcoat composition contains an organic solvent, such as those mentioned previously. The solvent in the overcoat composition may be any suitable solvent that does not dissolve the relief pattern.

### Quencher

A quencher may be included in the overcoat composition, such as to help control diffusion or action of an active material in/of the SSA. As such, suitable quenchers are chosen specifically to shut down, or quench, the action of the SSA. For example, in embodiments where the SSA is an acid, suitable quenchers may be bases or base generators and in embodiments where the SSA is a base, suitable quenchers may be acids or acid generators.

Some suitable example quenchers are acids or acid generators including linear or branched (C₄₋₁₂)carboxylic acids such as butyric acid, caproic acid, lauric acid, benzoic acid and bezenedicarboxylic acid, oxalic acid, malonic acid, maleic acid, tartaric acid or succinic acid; alkyl sulfonic acids such as methanesulfonic acid, triflic acid, ethanesulfonic acid, ethanedisulfonic acid, butanesulfonic acid, perfluorobutanesulfonic acid, octanesulfonic acid, perfluorooctanesulfonic acid and camphorsulfonic acid; arylsulfonic acids such as benzenesulfonic acid, tosylic acid, nitrobenzenesulfonic acid (ortho, meta or para), xylenesulfonic acid, mesitylenesulfonic acid, naphthylenesulfonic acid, dodecylbezenesulfonic acid, 4,5-di(nonyl)naphthalene-2-sulfonic acid, 5-Sulfoisophthalic acid; sulfamic acids such as methanesulfonamide, dimethanesulfonamide, bis(trifluoromethane)sulfonimide, 1,3,2-dithiazinane 1,1,3,3-tetraoxide, 1,1,2,2,3,3-hexafluoropropane-1,3-disulfonimide; other super acids such as tris (trifluoromethanesulfonyl) methane.

Some suitable example quenchers are bases or base generators and include hydroxides, carboxylates, amines, imines, amides, or mixtures thereof. Some specific examples of bases are ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, tetraethylammonium phosphate, tetrabutylammonium hydroxide, or combinations thereof.

Some example amines are aliphatic amines, cycloaliphatic amines, aromatic amines, or heterocyclic amines. The amine may be a primary, secondary, or tertiary amine. The amine may be a monoamine, diamine, or polyamine. Suitable amines may include C₁₋₃₀ organic amines, imines, amides, or carbamates, or may be a C₁₋₃₀ quaternary ammonium salt of a strong base (e.g., a hydroxide or alkoxide) or a weak base (e.g., a carboxylate). In some embodiments, bases include amines such as tripropylamine, dodecylamine, tris(2-hydroxypropyl) amine, tetrakis (2-hydroxypropyl)ethylenediamine; aryl amines such as pyridine (optionally substituted), diphenylamine, phenethylamine, tryptamine, triphenylamine, aminophenol, and 2-(4-aminophenyl)-2-(4-hydroxyphenyl)propane, Troger's base, a hindered amine such as diazabicycloundecene (DBU) or diazabicyclononene (DBN), amides like tert-butyl 1,3-dihydroxy-2-(hydroxymethyl)propan-2-ylcarbamate and tert-butyl 4-hydroxypiperidine-1-carboxylateor; carbamates such as 1-Boc-4-hydroxypiperidine and tert-butyl N-[2-hydroxy-1,1-bis(hydroxymethyl)-ethyl]carbamate; or ionic quenchers including quaternary alkyl ammonium salts such as tetrabutylammonium hydroxide (TBAH) or tetrabutylammonium lactate.

In some embodiments, the amine is a hydroxyamine. Examples of hydroxyamines include hydroxyamines having one or more hydroxyalkyl groups each having 1 to about 8 carbon atoms, and sometimes preferably 1 to about 5 carbon atoms such as hydroxymethyl, hydroxyethyl and hydroxybutyl groups. Specific examples of hydroxy amines include mono-, di-and tri-ethanolamine, triisopropylamine, 3-amino-1-propanol, 2-amino-2-methyl-1-propanol, 2-amino-2-ethyl-1,3-propanediol, tris(hydroxymethyl) aminomethane, N-methylethanolamine, and 2-diethylamino-2-methyl-1-propanol.

In an embodiment, a TBG (thermal base generator) is included as a base generator in the overcoat composition. Suitable TBGs may be similar to those previously described. A quencher may be included in the overcoat composition in non-polymeric, polymer-bound form, or ligand-bound form. When in polymeric form, the quencher may be present in polymerized units on the polymer. When in ligand form, the quencher may be present as one or more ligands in an organometallic complex.

Example embodiments of the invention are summarized here. Other embodiments can also be understood from the entirety of the specification as well as the claims filed herein.

Example 1. An SSA coating composition including: an SSA configured to be diffused inward into a relief pattern from an SSA coating formed from the SSA coating composition, to remain dormant within structures of the relief pattern during a photolithographic process, and to be diffused outward from the relief pattern into an overcoat, the relief pattern including a metal-based resist; a matrix polymer including at least one monomer; and a solvent configured to dissolve the SSA and the matrix polymer, but not the metal-based resist.

Example 2. The SSA coating composition of example 1, where the at least one monomer includes a monomer with an ethylenically unsaturated polymerizable double bond.

Example 3. The SSA coating composition of example 2, where the at least one monomer includes a (meth) acryl-based monomer.

Example 4. The SSA coating composition of one of examples 2 and 3, where the at least one monomer includes a vinyl-based monomer.

Example 5. The SSA coating composition of one of examples 2 to 4, where the at least one monomer includes a maleic-based monomer.

Example 6. The SSA coating composition of one of examples 2 to 5, where the at least one monomer includes a norbornene-based monomer.

Example 7. The SSA coating composition of one of examples 1 to 6, further including: an attachment agent including a chemical functional group configured to selectively adhere to the relief pattern.

Example 8. The SSA coating composition of one of examples 1 to 7, where the SSA includes an activatable free acid.

Example 9. The SSA coating composition of one of examples 1 to 8, where the SSA includes a TAG.

Example 10. The SSA coating composition of one of examples 1 to 9, where the SSA includes a PAG.

Example 11. The SSA coating composition of one of examples 1 to 10, where the SSA includes an oxidizing agent, a reducing agent, or a free ligand.

Example 12. A method for self-aligned double patterning, the method including: diffusing an SSA inward from an SSA coating into structures of a relief pattern formed on a substrate, the relief pattern including a metal-based resist; rinsing the substrate to remove the SSA coating leaving the relief pattern with the metal-based resist and the SSA; depositing an overcoat including a solubility-shiftable resist in openings of the relief pattern; diffusing the SSA outward from the structures of the relief pattern into the overcoat to form soluble regions in the overcoat; and developing the substrate to selectively remove the soluble regions and form trenches between the structures of the relief pattern and remaining structures of the overcoat.

Example 13. The method of example 12, further including: coating the relief pattern with the SSA coating before diffusing the SSA inward from the SSA coating into the structures of the relief pattern.

Example 14. The method of one of examples 12 and 13, where the solubility-shiftable resist includes metal atoms and organic ligands.

Example 15. The method of example 14, where the metal atoms of the solubility-shiftable resist of the overcoat are substantially similar to the metal-based resist of the relief pattern.

Example 16. The method of one of examples 12 and 13, where the solubility-shiftable resist is a polymer-based resist.

Example 17. The method of example 16, where the polymer-based resist includes a backbone degradable polymer.

Example 18. A method for self-aligned double patterning, the method including: diffusing an SSA inward from an SSA coating into structures of a relief pattern formed on a substrate, the relief pattern including a metal-based resist, the SSA being a free ligand; rinsing the substrate to remove the SSA coating leaving the relief pattern with the metal-based resist and the SSA; depositing an overcoat including a solubility-shiftable resist in openings of the relief pattern, the solubility-shiftable resist including metal atoms and organic ligands; diffusing the SSA outward from the structures of the relief pattern into the overcoat to form soluble regions in the overcoat; and developing the substrate to selectively remove the soluble regions and form trenches between the structures of the relief pattern and remaining structures of the overcoat.

Example 19. The method of example 18, further including: coating the relief pattern with the SSA coating before diffusing the SSA inward from the SSA coating into the structures of the relief pattern.

Example 20. The method of one of examples 18 and 19, where the metal atoms of the solubility-shiftable resist of the overcoat are substantially similar to the metal-based resist of the relief pattern.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A solubility-shifting agent (SSA) coating composition comprising:
an SSA configured to be diffused inward into a relief pattern from an SSA coating formed from the SSA coating composition, to remain dormant within structures of the relief pattern during a photolithographic process, and to be diffused outward from the relief pattern into an overcoat, the relief pattern comprising a metal-based resist;
a matrix polymer comprising at least one monomer; and
a solvent configured to dissolve the SSA and the matrix polymer, but not the metal-based resist.

2. The SSA coating composition of claim 1, wherein the at least one monomer comprises a monomer with an ethylenically unsaturated polymerizable double bond.

3. The SSA coating composition of claim 2, wherein the at least one monomer comprises a (meth)acryl-based monomer.

4. The SSA coating composition of claim 2, wherein the at least one monomer comprises a vinyl-based monomer.

5. The SSA coating composition of claim 2, wherein the at least one monomer comprises a maleic-based monomer.

6. The SSA coating composition of claim 2, wherein the at least one monomer comprises a norbornene-based monomer.

7. The SSA coating composition of claim 1, further comprising:
an attachment agent comprising a chemical functional group configured to selectively adhere to the relief pattern.

8. The SSA coating composition of claim 1, wherein the SSA is an activatable free acid.

9. The SSA coating composition of claim 1, wherein the SSA comprises a thermal acid generator (TAG).

10. The SSA coating composition of claim 1, wherein the SSA comprises a photoacid generator (PAG).

11. The SSA coating composition of claim 1, wherein the SSA comprises an oxidizing agent, a reducing agent, or a free ligand.

12. A method for self-aligned double patterning, the method comprising:
diffusing a solubility-shifting agent (SSA) inward from an SSA coating into structures of a relief pattern formed on a substrate, the relief pattern comprising a metal-based resist;
rinsing the substrate to remove the SSA coating leaving the relief pattern with the metal-based resist and the SSA;
depositing an overcoat comprising a solubility-shiftable resist in openings of the relief pattern;
diffusing the SSA outward from the structures of the relief pattern into the overcoat to form soluble regions in the overcoat; and
developing the substrate to selectively remove the soluble regions and form trenches between the structures of the relief pattern and remaining structures of the overcoat.

13. The method of claim 12, further comprising:
coating the relief pattern with the SSA coating before diffusing the SSA inward from the SSA coating into the structures of the relief pattern.

14. The method of claim 12, wherein the solubility-shiftable resist comprises metal atoms and organic ligands.

15. The method of claim 14, wherein the metal atoms of the solubility-shiftable resist of the overcoat are substantially similar to the metal-based resist of the relief pattern.

16. The method of claim 12, wherein the solubility-shiftable resist is a polymer-based resist.

17. The method of claim 16, wherein the polymer-based resist comprises a backbone degradable polymer.

18. A method for self-aligned double patterning, the method comprising:
diffusing a solubility-shifting agent (SSA) inward from an SSA coating into structures of a relief pattern formed on a substrate, the relief pattern comprising a metal-based resist, the SSA being a free ligand;
rinsing the substrate to remove the SSA coating leaving the relief pattern with the metal-based resist and the SSA;
depositing an overcoat comprising a solubility-shiftable resist in openings of the relief pattern, the solubility-shiftable resist comprising metal atoms and organic ligands;
diffusing the SSA outward from the structures of the relief pattern into the overcoat to form soluble regions in the overcoat; and
developing the substrate to selectively remove the soluble regions and form trenches between the structures of the relief pattern and remaining structures of the overcoat.

19. The method of claim 18, further comprising:
coating the relief pattern with the SSA coating before diffusing the SSA inward from the SSA coating into the structures of the relief pattern.

20. The method of claim 18, wherein the metal atoms of the solubility-shiftable resist of the overcoat are substantially similar to the metal-based resist of the relief pattern.
